(19) United States
(12) Patent Application Publication
(10) Pub. No.: US 2024/0008300 A1
(43) Pub. Date: Jan. 4, 2024

(54) TOP-EMISSION ORGANIC ELECTROLUMINESCENT DEVICE

(71) Applicant: BEIJING SUMMER SPROUT TECHNOLOGY CO., LTD., Beijing (CN)

(72) Inventors: Jing WANG, Beijing (CN); Menglan XIE, Beijing (CN); Huiqing PANG, Beijing (CN); Chi Yuen Raymond KWONG, Beijing (CN); Chuanjun XIA, Beijing (CN)

(21) Appl. No.: 18/215,407

(22) Filed: Jun. 28, 2023

(30) Foreign Application Priority Data
Jun. 29, 2022 (CN) 202210734050.7

(51) Int. Cl. H10K 50/12; H10K 50/81; H10K 50/826

(52) U.S. Cl. CPC H10K 50/12; H10K 50/81; H10K 50/826; H10K 2102/3026

(57) ABSTRACT

Provided is a top-emission organic electroluminescent device, comprising an anode, a cathode and an emissive layer disposed between the two electrodes; the emissive doped material of the emissive layer has a λₘₐₓ, the device has a maximum external quantum efficiency conversion rate E=EQE_{A}/EQE_{B}, and satisfies when 500 nm≤λₘₐₓ≤600 nm, E≥1.625; when 600 nm<λₘₐₓ≤700 nm, E≥1.850, and the bottom-emission device has an exciton recombination region whose peak position is located in the emissive layer in a region >0% and ≤65% of thickness thereof from the side close to the anode. The top-emission device exhibits more excellent device performance. Further provided are a display assembly comprising the top-emission device and use of the top-emission device in an electronic device, an electronic element module, a display device or a lighting device.

### CROSS-REFERENCE TO RELATED APPLICATION(S)

This application claims priority to Chinese Patent Application No. 202210734050.7 filed on Jun. 29, 2022, the disclosure of which is incorporated herein by reference in its entirety.

### TECHNICAL FIELD

The present disclosure relates to a top-emission organic electroluminescent device. More specifically, the present disclosure relates to a top-emission organic electroluminescent device with a high-efficiency conversion rate and a display assembly comprising the top-emission organic electroluminescent device.

### BACKGROUND

Since C. W. Tang and Van Slyke reported a high-brightness and low-voltage organic electroluminescent device in 1987, organic electroluminescence has been developed rapidly. With the increasing mature of the research on monochromatic organic electroluminescent devices with three primary colors: red, green and blue, especially the improvement of the performance of the blue-light device, such as the brightness and the lifetime. The organic electroluminescent device has entered a stage of actual application and has been widely used in daily used electronic products. In an actual commercial use, a large area and an active driving technology are mainstreams of an organic electroluminescence display technology at present. To achieve large-size display, a TFT backplane driving technology needs to be used. Based on this, the preparation of a traditional bottom-emission (BE) organic electroluminescent device (hereinafter referred to as a bottom-emission device) brings about the problem of low aperture ratio. Therefore, to achieve an active-driven, large-area and high-brightness organic electroluminescence display screen, a top-emission (TE) organic electroluminescent device (hereinafter referred to as a top-emission device) needs to be used. Among commercialized organic electroluminescent devices at present, generally, a top-emission organic light-emitting device is prepared and an optical microcavity in the device is adjusted to meet a requirement of the International Commission for Electrons and Optics for a color coordinate of a display.

As previously described, the commercial devices at present are top-emission devices. However, since the top-emission device has an optical microcavity effect, intrinsic characteristics of a material (for example, a spectrum of the top-emission device cannot reflect an intrinsic spectral shape of an emissive layer) are covered up, and for the top-emission device, a thickness of a film needs to be adjusted to adjust the microcavity to obtain a comprehensive evaluation of device performance, thereby increasing the number of experiments and resulting in a relatively high preparation cost. Therefore, the top-emission device is not the most suitable device structure for performing a performance evaluation of a new material. Since the bottom-emission device can well reflect the intrinsic characteristics of the material and is simple to prepare and low in cost, research and development personnel generally use the bottom-emission device to perform an initial evaluation of the performance of the new material when developing the new material, and then use a potential material in the top-emission device to save the time and the cost. Therefore, it is necessary to study an association of performance between a bottom-emission device and a top-emission device having the same device structure. If the device performance of the bottom-emission device can be associated to a certain extent with the performance of the top-emission device having the same device structure, the time and cost for material development and screening can be significantly saved.

In a mature organic electroluminescent device structure in the industry, an anode, a hole transporting region, an emissive layer (EML), an electron transporting region and a cathode (the cathode may further comprise an electron injection layer (EIL), constituting a multi-stack cathode) are generally comprised, where the hole transporting region may comprise a hole injection layer (HIL), a hole transporting layer (HTL), an electron blocking layer (EBL), and the electron transporting region may comprise a hole blocking layer (HBL) and an electron transporting layer (ETL). The HBL and/or the EBL may be selectively present due to different device structures. One or more layers of the same functional layer, for example, one or more layers of the HIL, may be used according to different requirements and optimization results of the device.

A working principle of the organic electroluminescent device is as follows: electrons and holes are injected through the cathode and the anode of the device under the drive of a certain voltage into the electron transporting region and the hole transporting region from the cathode and the anode, respectively, and then separately migrated to the emissive layer, the electrons and the holes are recombined to form excitons in the emissive layer, and visible light is emitted after the exciton recombination. Therefore, studying the exciton recombination behavior in the emissive layer is an important factor in studying the device performance.

### SUMMARY

In view of the above problems, the present disclosure aims to provide a high-efficiency top-emission organic electroluminescent device. The top-emission organic electroluminescent device comprises an anode, a multi-stack cathode and an emissive layer disposed between the two electrodes. The emissive layer comprises an emissive doped material, wherein a maximum emission wavelength of the emissive doped material is λₘₐₓ, and 500 nm≤λₘₐₓ≤700 nm. The top-emission organic electroluminescent device has a maximum external quantum efficiency conversion rate E, wherein when 500 nm≤λₘₐₓ≤600 nm, E≥1.625; when 600 nm<λₘₐₓ≤700 nm, E≥1.850; and E=EQE_{A}/EQE_{B}. EQE_{A} is maximum external quantum efficiency of the top-emission device at a current density of Jₒ, and EQE_{B} is maximum external quantum efficiency of a bottom-emission device at the current density of J₀. The bottom-emission device has the same device structure as the top-emission device. The bottom-emission device has an exciton recombination region, and the exciton recombination peak position is located in the emissive layer within a region greater than 0% and less than or equal to 65% of the thickness of the emissive layer from the side close to the anode.

According to an embodiment of the present disclosure, disclosed is a top-emission organic electroluminescent device, which comprises:
an anode, a multi-stack cathode and an emissive layer disposed between the anode and the multi-stack cathode;
wherein the emissive layer comprises an emissive doped material, wherein a maximum emission wavelength of a photoluminescence spectrum of the emissive doped material is λₘₐₓ, and 500 nm≤λₘₐₓ≤700 nm;
the top-emission organic electroluminescent device has a maximum external quantum efficiency conversion rate E, wherein E=EQE_{A}/EQE_{B} and conforms to: when 500 nm≤λₘₐₓ≤600 nm, E≥1.625; when 600 nm<λₘₐₓ≤700 nm, E≥1.850;
EQE_{A} is maximum external quantum efficiency of the top-emission organic electroluminescent device at a current density of Jₒ;
EQE_{B} is maximum external quantum efficiency of a bottom-emission organic electroluminescent device at the current density of Jₒ;
the bottom-emission organic electroluminescent device has the same device structure as the top-emission organic electroluminescent device; and
the emissive layer of the bottom-emission organic electroluminescent device has an exciton recombination region, and an exciton recombination peak position is located in the emissive layer of the bottom-emission organic electroluminescent device within a region greater than 0% and less than or equal to 65% of the thickness of the emissive layer from the side close to the anode.

According to an embodiment of the present disclosure, disclosed is a top-emission organic electroluminescent device, which comprises an anode, a cathode and an emissive layer disposed between the anode and the cathode;
wherein the emissive layer comprises an emissive doped material;
a maximum emission wavelength of a photoluminescence spectrum of the emissive doped material is λₘₐₓ, and 500 nm≤λₘₐₓ≤700 nm; and
the emissive layer has an exciton recombination region, and an exciton recombination peak position is located in the emissive layer within a region greater than 0% and less than or equal to 65% of the thickness of the emissive layer from the side close to the anode.

According to an embodiment of the present disclosure, further disclosed is a display assembly, which comprises the top-emission organic electroluminescent device in the preceding embodiment.

According to an embodiment of the present disclosure, further disclosed is a use of the top-emission organic electroluminescent device in the preceding embodiment in an electronic device, an electronic element module, a display device or a lighting device.

In the present application, through researches on the exciton recombination peak position of the bottom-emission device having the same device structure as the top-emission organic electroluminescent device and the efficiency conversion rate E between the bottom-emission device and the top-emission device, it is found that compared to other top-emission organic electroluminescent devices, the top-emission organic electroluminescent device of the present disclosure can exhibit more excellent device performance even if the same organic emissive doped material is used.

### BRIEF DESCRIPTION OF DRAWINGS

FIG. 1 is a sectional view of a top-emission organic electroluminescent device 100.

FIG. 2 is a sectional view of a bottom-emission organic electroluminescent device 200.

FIG. 3 is a schematic diagram illustrating a position distribution of a probe layer in an EML.

FIG. 4a is a schematic diagram illustrating exciton fraction distributions at different positions in EMLs of Bottom-emission Device Examples 1-1, 1-2 and 1-5 of the present disclosure.

FIG. 4b is a diagram illustrating distributions of the maximum external quantum efficiency and the maximum external quantum efficiency conversion rates E of top-emission device examples 1-1, 1-2 and 1-5 of the present disclosure.

FIG. 5a is a schematic diagram illustrating exciton fraction distributions at different positions in EMLs of Bottom-emission Device Examples 1-3, 1-4 and 1-6 of the present disclosure.

FIG. 5b is a diagram illustrating distributions of the maximum external quantum efficiency and the maximum external quantum efficiency conversion rates E of Bottom-emission Device Examples 1-3, 1-4 and 1-6 of the present disclosure.

FIG. 6a is a schematic diagram illustrating exciton fraction distributions at different positions in EMLs of Bottom-emission Device Examples 1-7, 1-8 and 1-9 of the present disclosure.

FIG. 6b is a diagram illustrating distributions of the maximum external quantum efficiency and the maximum external quantum efficiency conversion rates E of Bottom-emission Device Examples 1-7, 1-8 and 1-9 of the present disclosure.

FIG. 7 is a sectional view of a top-emission organic electroluminescent device 300.

FIG. 8 is a sectional view of a bottom-emission organic electroluminescent device 400.

FIG. 9 is a schematic diagram illustrating an exciton fraction distribution at different positions in an EML of Bottom-emission Device Example 1-10.

### DETAILED DESCRIPTION

As used in herein, “top” means furthest away from a substrate, while “bottom” means

closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, the term “OLED device” comprises an anode layer, a cathode layer and one or more organic layers disposed between the anode layer and the cathode layer. An “OLED device” may be bottom-emission, that is, light is emitted from the substrate (a bottom-emission device), or may be top-emission, that is, light is emitted from the encapsulation layer (a top-emission device), or may be a transparent device, that is, light is emitted from both the substrate and the encapsulation side at the same time.

As used herein, the term “encapsulation layer” may be a thin film encapsulation with a thickness of less than 100 micrometers, which includes one or more thin films directly disposed on the device, or may be a cover glass glued to the substrate.

As used herein, the term “light extraction layer” may refer to a light diffuser film, or other microstructures having a light extraction effect, or a thin film coating having a light out-coupling effect. The light extraction layer may be disposed on a substrate surface of the OLED, and may also be disposed at other suitable positions, such as between the substrate and the anode, or between the organic layer and the cathode, or between the cathode and the encapsulation layer, or a surface of the encapsulation layer.

The sectional views of the organic electroluminescent devices provided in the specific embodiments of the present disclosure are schematically shown without limitation. The figures are not necessarily drawn to scale. Some of the layer structures in the figures can also be added or omitted as needed. Substrates of the organic electroluminescent devices can be fabricated on various types of substrates such as glass, plastic, and metal. The properties and functions of these various layers, as well as example materials, are described in more detail in U.S. Pat. No. 7,279,704 at cols. 6-10, the contents of which are incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

### Definition of Terms of Substituents

Halogen or halide—as used herein includes fluorine, chlorine, bromine, and iodine.

Alkyl—as used herein includes both straight and branched chain alkyl groups. Alkyl

may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanyl ethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethyl silylsopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3 -diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3 -dimethyl-1-butynyl, 3 -ethyl-3 -methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by -O-alkyl, -O-cycloalkyl, -O-heteroalkyl, or -O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by -O-aryl or -O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

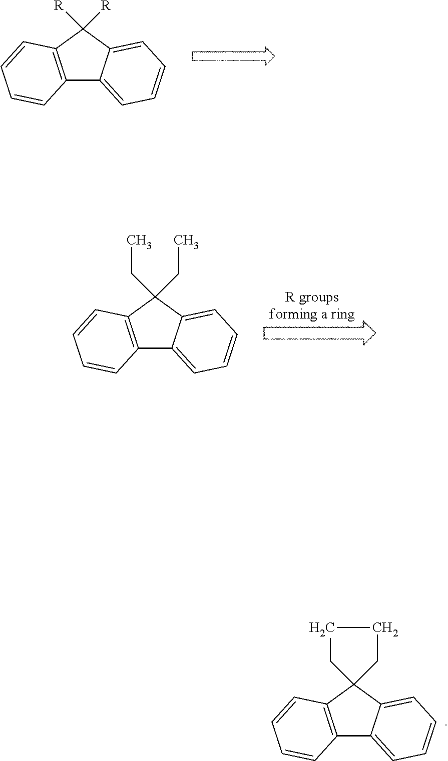

The expression that adjacent substituents can be optionally joined to form a ring is also intended to mean that two substituents bonded to carbon atoms which are directly bonded to each other are joined to each other via a chemical bond to form a ring, which can be exemplified by the following formula:

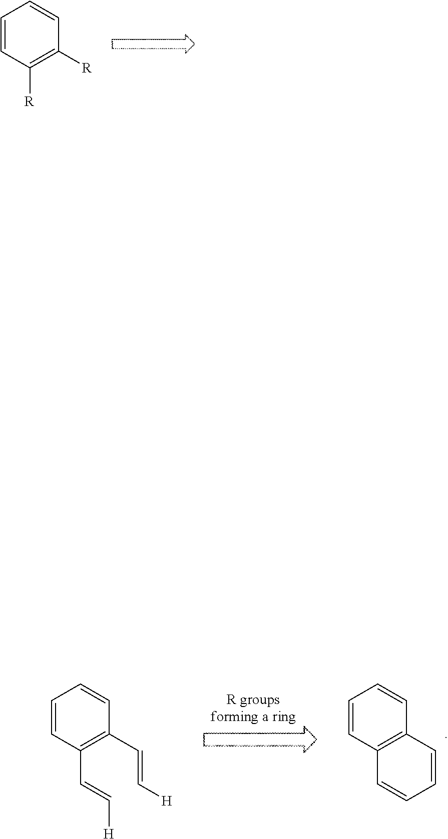

The expression that adjacent substituents can be optionally joined to form a ring is also intended to mean that two substituents bonded to a further distant carbon atom are joined to each other via a chemical bond to form a ring, which can be exemplified by the following formula:

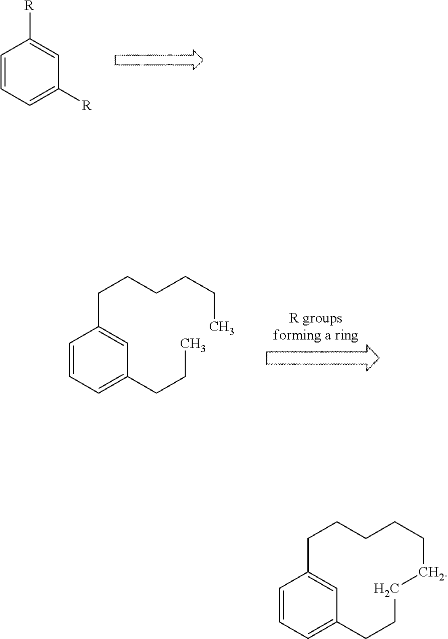

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

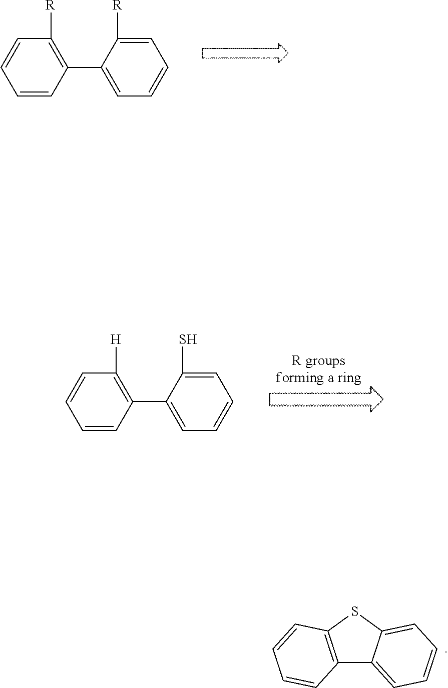

According to an embodiment of the present disclosure, disclosed is a top-emission organic electroluminescent device, which comprises:
an anode, a multi-stack cathode and an emissive layer disposed between the anode and the multi-stack cathode;
wherein the emissive layer comprises an emissive doped material, wherein a maximum emission wavelength of a photoluminescence spectrum of the emissive doped material is λₘₐₓ, and 500 nm≤λₘₐₓ≤700 nm;
the top-emission organic electroluminescent device has a maximum external quantum efficiency conversion rate E, wherein E=EQE_{A}/EQE_{B} and conforms to: when 500 nm≤λₘₐₓ≤600 nm, E≥1.625; when 600 nm<λₘₐₓ≤700 nm, E≥1.850;
EQE_{A} is maximum external quantum efficiency of the top-emission organic electroluminescent device at a current density of Jₒ;
EQE_{B} is maximum external quantum efficiency of a bottom-emission organic electroluminescent device at the current density of Jₒ;
the bottom-emission organic electroluminescent device has the same device structure as the top-emission organic electroluminescent device; and
the emissive layer of the bottom-emission organic electroluminescent device has an exciton recombination region, and an exciton recombination peak position is located in the emissive layer of the bottom-emission organic electroluminescent device within a region greater than 0% and less than or equal to 65% of the thickness of the emissive layer from the side close to the anode.

According to an embodiment of the present disclosure, disclosed is a top-emission organic electroluminescent device, which comprises a first anode; a first multi-stack cathode; and a first hole transporting region, a first emissive layer and a first electron transporting region that are disposed between the first anode and the first multi-stack cathode;
wherein the first hole transporting region is located between the first anode and the first emissive layer, and the first electron transporting region is located between the first emissive layer and the first multi-stack cathode;
the first emissive layer comprises an emissive doped material, wherein a maximum emission wavelength of a photoluminescence spectrum of the emissive doped material is λₘₐₓ, and 500 nm≤λₘₐₓ≤700 nm;
the top-emission organic electroluminescent device has a maximum external quantum efficiency conversion rate E, wherein E=EQE_{A}/EQE_{B}, and:
when 500 nm≤λₘₐₓ≤600 nm, E≥1.625;
when 600 nm<λₘₐₓ≤700 nm, E≥1.850;
EQE_{A} is maximum external quantum efficiency of the top-emission organic electroluminescent device at a current density of Jₒ;
EQE_{B} is maximum external quantum efficiency of a bottom-emission organic electroluminescent device at the current density of Jₒ;
the bottom-emission organic electroluminescent device comprises a second anode; a second multi-stack cathode; and a second hole transporting region, a first emissive layer and a first electron transporting region that are disposed between the second anode and the second multi-stack cathode;
wherein the second hole transporting region is located between the second anode and the first emissive layer, and the first electron transporting region is located between the first emissive layer and the second multi-stack cathode;
the bottom-emission organic electroluminescent device has an exciton recombination region, and an exciton recombination peak position is located in the first emissive layer within a region greater than 0% and less than or equal to 65% of the thickness of the first emissive layer from the side close to the second anode; and
the first hole transporting region and the second hole transporting region comprise the same one or more organic layers, and the same one or more organic layers have the same material type and mass ratio, except for a thickness.

According to an embodiment of the present disclosure, disclosed is a top-emission organic electroluminescent device, which comprises a cathode, an anode and an emissive layer disposed between the cathode and the anode;
wherein the emissive layer comprises an emissive doped material;
a maximum emission wavelength of a photoluminescence spectrum of the emissive doped material is max, and 500 nm≤λₘₐₓ≤700 nm; and
the emissive layer has an exciton recombination region, and an exciton recombination peak position is located in the emissive layer within a region greater than 0% and less than or equal to 65% of the thickness of the emissive layer from the side close to the anode.

In this embodiment, the exciton recombination region is obtained via determination on a bottom-emission device having the same device structure as the top-emission device. For a specific test method, reference is made to an explanation of the term “exciton recombination peak position” in the present application.

According to an embodiment of the present disclosure, the first anode/anode has a reflectivity of greater than or equal to 85% at 550 nm.

According to an embodiment of the present disclosure, the first anode/anode has a reflectivity of greater than or equal to 90% at 550 nm.

According to an embodiment of the present disclosure, the first anode/anode has a reflectivity of greater than or equal to 95% at 550 nm.

According to an embodiment of the present disclosure, the first anode/anode is selected from the group consisting of the following materials: silver, aluminum, titanium, nickel, platinum, a combination of silver, aluminum, titanium, nickel or platinum and indium tin oxide (ITO), indium zinc oxide (IZO), molybdenum oxide (MoOx) or titanium nitride (TiN), and combinations thereof.

According to an embodiment of the present disclosure, the second anode has a transmittance of greater than or equal to 80% at 550 nm.

According to an embodiment of the present disclosure, the second anode has a transmittance of greater than or equal to 84% at 550 nm.

According to an embodiment of the present disclosure, the second anode has a transmittance of greater than or equal to 89% at 550 nm.

According to an embodiment of the present disclosure, the second anode is selected from the group consisting of the following materials: indium tin oxide (ITO), indium zinc oxide (IZO), molybdenum oxide (MoOx) and combinations thereof.

According to an embodiment of the present disclosure, when 500 nm≤λₘₐₓ≤600 nm, the second anode is ITO with a thickness of greater than or equal to 700 Å and less than or equal to 900 Å.

According to an embodiment of the present disclosure, when 600 nm<λₘₐₓ≤700 nm, the second anode is ITO with a thickness range of greater than or equal to 1100 Å and less than or equal to 1300 Å.

According to an embodiment of the present disclosure, the exciton recombination peak position is located in the emissive layer within a region less than 50% of the thickness of the emissive layer from the side close to the anode.

According to an embodiment of the present disclosure, the exciton recombination peak position is located in the emissive layer within a region less than 40% of the thickness of the emissive layer from the side close to the anode.

According to an embodiment of the present disclosure, the exciton recombination peak position is located in the emissive layer within a region less than 30% of the thickness of the emissive layer from the side close to the anode.

According to an embodiment of the present disclosure, the exciton recombination peak position is located in the emissive layer within a region greater than 2.5% of the thickness of the emissive layer from the side close to the anode.

According to an embodiment of the present disclosure, the exciton recombination peak position is located in the emissive layer within a region greater than 5% of the thickness of the emissive layer from the side close to the anode.

According to an embodiment of the present disclosure, the exciton recombination peak position is located in the emissive layer within a region greater than 7.5% of the thickness of the emissive layer from the side close to the anode.

According to an embodiment of the present disclosure, a distance between the exciton recombination peak position and the interface of the emissive layer on the side close to the anode is greater than 1 nm.

According to an embodiment of the present disclosure, the distance between the exciton recombination peak position and the interface of the emissive layer on the side close to the anode is greater than 3 nm.

According to an embodiment of the present disclosure, when 500 nm≤λₘₐₓ≤600 nm, E≥1.640; preferably, E≥1.660.

According to an embodiment of the present disclosure, when 600 nm<λₘₐₓ≤700 nm, E≥1.900; preferably, E≥2.000.

According to an embodiment of the present disclosure, when 500 nm≤λₘₐₓ≤600 nm, a full width at half maximum of the photoluminescence spectrum of the emissive doped material is less than or equal to 53 nm, or less than or equal to 45 nm, or less than or equal to 40 nm, or less than or equal to 35 nm.

According to an embodiment of the present disclosure, when 600 nm<λₘₐₓ≤700 nm, a full width at half maximum of the photoluminescence spectrum of the emissive doped material is less than or equal to 50 nm, or less than or equal to 40 nm, or less than or equal to 35 nm, or less than or equal to 30 nm.

According to an embodiment of the present disclosure, Jₒ is greater than 5 mA/cm² and less than or equal to 50 mA/cm².

According to an embodiment of the present disclosure, Jₒ is greater than 5 mA/cm² and less than or equal to 35 mA/cm².

According to an embodiment of the present disclosure, Jₒ is greater than 5 mA/cm² and less than or equal to 15 mA/cm².

According to an embodiment of the present disclosure, Jₒ is greater than 1 mA/cm² and less than or equal to 50 mA/cm².

According to an embodiment of the present disclosure, Jₒ is greater than 3 mA/cm² and less than or equal to 35 mA/cm².

According to an embodiment of the present disclosure, Jₒ is greater than 5 mA/cm² and less than or equal to 15 mA/cm².

According to an embodiment of the disclosure, when 500 nm≤λₘₐₓ≤600 nm, under a condition that Jₒ is 10 mA/cm², EQE_{B}≥23.0%.

According to an embodiment of the present disclosure, when 600 nm<λₘₐₓ≤700 nm, under the condition that Jₒ is 10 mA/cm², EQE_{B}≥24.0%.

According to an embodiment of the disclosure, when 500 nm≤λₘₐₓ≤600 nm, under a condition that Jₒ is 10 mA/cm², EQE_{A}≥37.0%.

According to an embodiment of the present disclosure, when 600 nm<λₘₐₓ≤700 nm, under the condition that Jₒ is 10 mA/cm², EQE_{A}≥50%.

According to an embodiment of the present disclosure, the emissive layer further comprises a first host material and/or a second host material.

According to an embodiment of the present disclosure, the emissive layer further comprises a first host material and/or a second host material, wherein the first host material is a p-type host material, and the second host material is an n-type material.

According to an embodiment of the present disclosure, when 500 nm≤λₘₐₓ≤600 nm, an HOMO energy level of the emissive doped material <−5.100 eV.

According to an embodiment of the present disclosure, when 600 nm<λₘₐₓ≤700 nm, the HOMO energy level of the emissive doped material <−5.110 eV.

According to an embodiment of the present disclosure, the first hole transporting region further comprises a first hole injection layer, a first hole transporting layer and/or a first electron blocking layer, and the second hole transporting region further comprises a first hole injection layer, a second hole transporting layer and/or a first electron blocking layer, wherein the first hole transporting layer and the second hole transporting layer comprise the same material type and doping proportion and only differs in thickness.

According to an embodiment of the present disclosure, the first hole transporting region further comprises a first hole injection layer, a first hole transporting layer and/or a first electron blocking layer, and the second hole transporting region further comprises a first hole injection layer, a first hole transporting layer and/or a second electron blocking layer, wherein the first electron blocking layer and the second electron blocking layer comprise the same material type and doping proportion and only differs in thickness.

According to an embodiment of the present disclosure, the first hole injection layer further comprises a p-type conductive doped material.

According to an embodiment of the present disclosure, disclosed is a display assembly, which comprises the top-emission organic electroluminescent device in any one of the preceding embodiments.

According to an embodiment of the present disclosure, further disclosed is a use of the top-emission organic electroluminescent device in any one of the preceding embodiments in an electronic device, an electronic element module, a display device or a lighting device.

According to an embodiment of the present disclosure, the emissive doped material has a general formula of M(Lₐ)ₘ(L_{b})ₙ(L_{c})_{q};
wherein the metal M is selected from a metal with a relative atomic mass greater than 40;
Lₐ, L_{b} and L_{c} are a first ligand, a second ligand and a third ligand coordinated to the metal M, respectively; the ligands Lₐ, L_{b}, and L_{c} may be identical or different;
the ligands Lₐ, L_{b} and L_{c} can be optionally joined to form a multidentate ligand;

m is 1, 2 or 3, n is 0, 1 or 2, q is 0, 1 or 2, and m+n+q is equal to an oxidation state of the metal M; when m is greater than or equal to 2, a plurality of Lₐ may be identical or different; when n is 2, two L_{b} may be identical or different; when q is 2, two L_{c} may be identical or different;

the ligand Lₐ has a structure represented by Formula 1 or Formula 2:

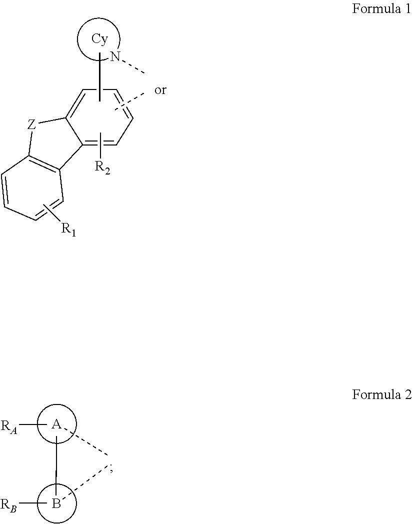

wherein
Cy is, at each occurrence identically or differently, selected from a substituted or unsubstituted heteroaromatic ring having 5 to 50 ring atoms;
Z is selected from the group consisting of O, S, Se, NR′, CR′R′, SiR′R′ and GeR′R′; when two R′ are present at the same time, the two R′ are identical or different;
the ring A and the ring B are, at each occurrence identically or differently, selected from a substituted or unsubstituted aromatic ring having 6 to 50 ring atoms, a substituted or unsubstituted heteroaromatic ring having 5 to 50 ring atoms or a combination thereof;
both the Ring A and the ring B are structures comprising at least two fused rings;
R₁, R₂, R_{A} and R_{B} represent, at each occurrence identically or differently, mono-substitution, multiple substitutions or non-substitution;
R′, R₁, R₂, R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of R₁ and R₂ is selected from halogen, substituted or unsubstituted aryl having 6 to 30 carbon atoms, substituted or unsubstituted heteroaryl having 3 to 30 carbon atoms or a cyano group;
in Formula 1, adjacent substituents R′, R₁ and R₂ can be optionally joined to form a ring;
in Formula 2, adjacent substituents R_{A} and R_{B} can be optionally joined to form a ring;
the ligands L_{b} and L_{c} are, at each occurrence identically or differently, selected from a monoanionic bidentate ligand; and

‘------ ’ represents a position where the ligand Lₐ is coordinated to the metal M.

In the present disclosure, the expression that “in Formula 1, adjacent substituents R′, R₁ and R₂ can be optionally joined to form a ring” is intended to mean that any one or more of groups of adjacent substituents, such as two substituents R′, two substituents R₁, two substituents R₂, substituents R′ and R₁, substituents R′ and R₂, and substituents R₁ and R₂, can be joined to form a ring. Obviously, it is also possible that none of these substituents are joined to form a ring.

In the present disclosure, the expression that “in Formula 2, adjacent substituents R_{A} and R_{B} can be optionally joined to form a ring” is intended to mean that any one or more of groups of adjacent substituents, such as two substituents R_{A}, two substituents R_{B}, and substituents R_{A} and R_{B}, can be joined to form a ring. Obviously, it is also possible that none of these substituents are joined to form a ring.

According to an embodiment of the present disclosure, the ligands L_{b} and L_{c} are, at each occurrence identically or differently, selected from any one or two of the following structures:

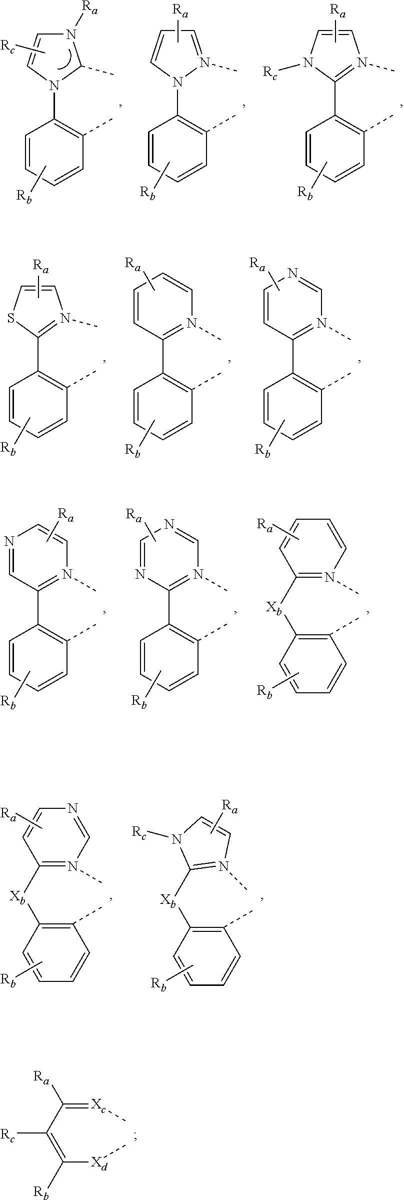

wherein
Rₐ, R_{b} and R_{c} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
X_{c} and X_{d} are, at each occurrence identically or differently, selected from the group consisting of: O, S, Se and NR_{N2};
Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{c}, R_{N1}, R_{N2}, R_{C1} and R_{C2} can be optionally joined to form a ring.

In the present disclosure, the expression that “adjacent substituents Rₐ, R_{b}, R_{c}, R_{N1}, R_{N2}, R_{C1} and R_{C2} can be optionally joined to form a ring” is intended to mean that any one or more of groups of adjacent substituents, such as two substituents Rₐ, two substituents R_{b}, two substituents R_{c}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, and substituents R_{C1} and R_{C2}, can be joined to form a ring. Obviously, it is also possible that none of these substituents are joined to form a ring.

According to an embodiment of the present disclosure, Cy is any structure selected from the group consisting of:

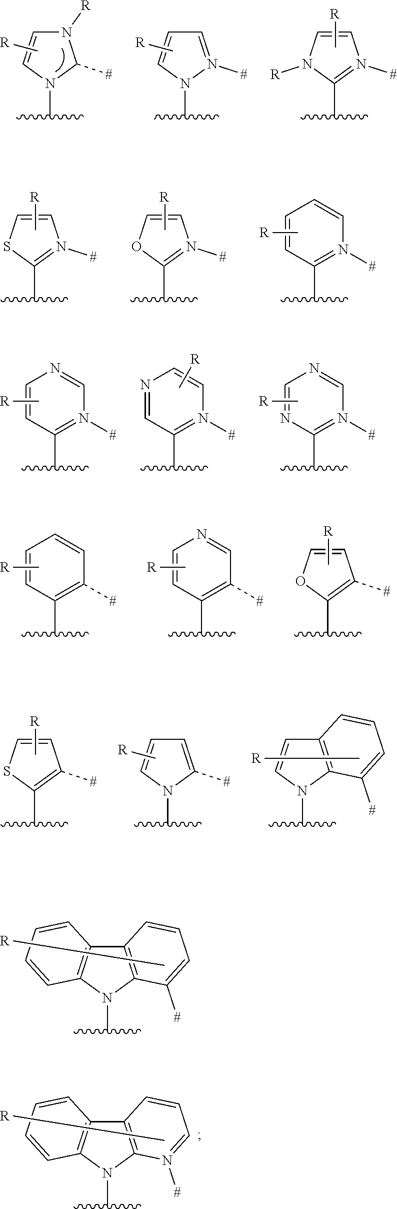

wherein
R represents, at each occurrence identically or differently, mono-substitution, multiple substitutions or non-substitution; when a plurality of R are present in any structure, the plurality of R are identical or different;
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
two adjacent substituents R can be optionally joined to form a ring; and
‘#’ represents a position where Cy is joined to the metal M, and

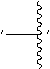

represents a position where Cy is joined to Formula 1.

In the present disclosure, the expression that “two adjacent substituents R can be optionally joined to form a ring” is intended to mean that any one or more of groups of any two adjacent substituents R can be joined to form a ring. Obviously, it is also possible that none of these substituents are joined to form a ring.

According to an embodiment of the present disclosure, the ligand Lₐ has a structure represented by any one of Formula 1-1 and Formulas 2-1 to 2-3:

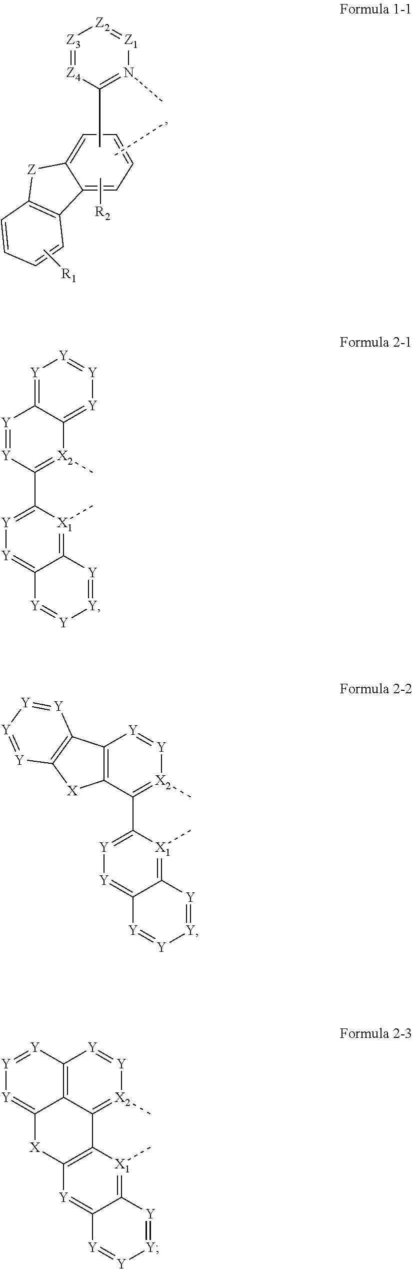

wherein X₁ and X₂ are, at each occurrence identically or differently, selected from C or N, X₁ and X₂ are not C at the same time, and X₁ and X₂ are not N at the same time;
Y is, at each occurrence identically or differently, selected from CR_{y} or N;
Z₁ to Z₄ are, at each occurrence identically or differently, selected from CR_{z} or N;
X and Z are selected from the group consisting of O, S, Se, NR′, CR′R′, SiR′R′ and GeR′R′; when two R′ are present at the same time, the two R′ are identical or different;
R₁ and R₂ represent, at each occurrence identically or differently, mono-substitution, multiple substitutions or non-substitution;
R′, R₁, R₂, R_{z} and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
at least one of R₁ and R₂ is selected from halogen, substituted or unsubstituted aryl having 6 to 30 carbon atoms, substituted or unsubstituted heteroaryl having 3 to 30 carbon atoms or a cyano group;
in Formula 1-1, adjacent substituents R′, R_{z}, R₁ and R₂ can be optionally joined to form a ring; and
in Formulas 2-1 to 2-3, adjacent substituents R′ and R_{y} can be optionally joined to form a ring.

In the present disclosure, the expression that “in Formula 1-1, adjacent substituents R′, R_{z}, R₁ and R₂ can be optionally joined to form a ring” is intended to mean that any one or more of groups of adjacent substituents, such as two substituents R′, two substituents R_{z}, two substituents R₁, two substituents R₂, substituents R′ and R₁, substituents R′ and R₂, and substituents R₁ and R₂, can be joined to form a ring. Obviously, it is also possible that none of these substituents are joined to form a ring.

In the present disclosure, the expression that “in Formulas 2-1 to 2-3, adjacent substituents R′ and R_{y} can be optionally joined to form a ring” is intended to mean that any one or more of groups of adjacent substituents, such as two substituents R′, two substituents R_{y}, and substituents R′ and R_{y}, can be joined to form a ring. Obviously, it is also possible that none of these substituents are joined to form a ring.

According to an embodiment of the present disclosure, the emissive doped material is selected from the group consisting of the following compounds which are included without limitation:

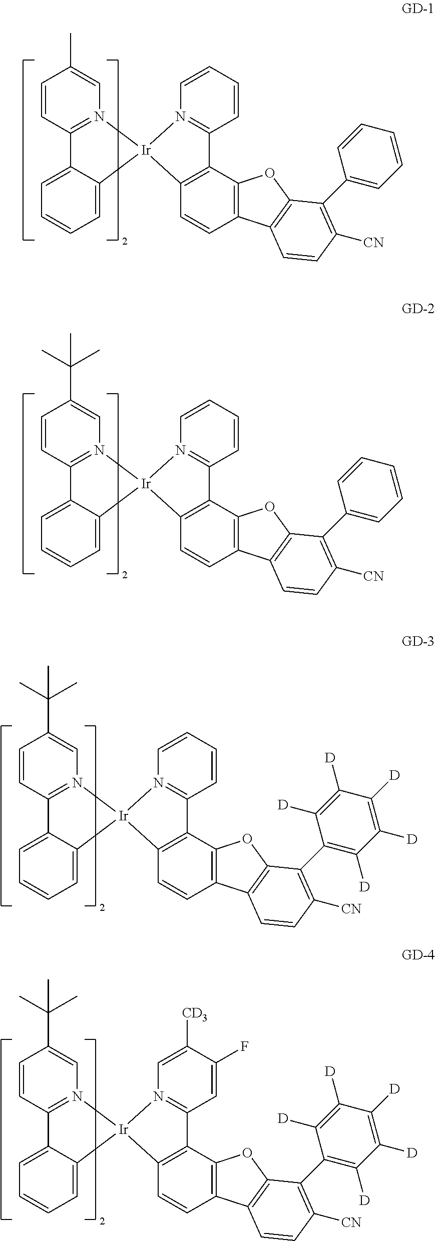

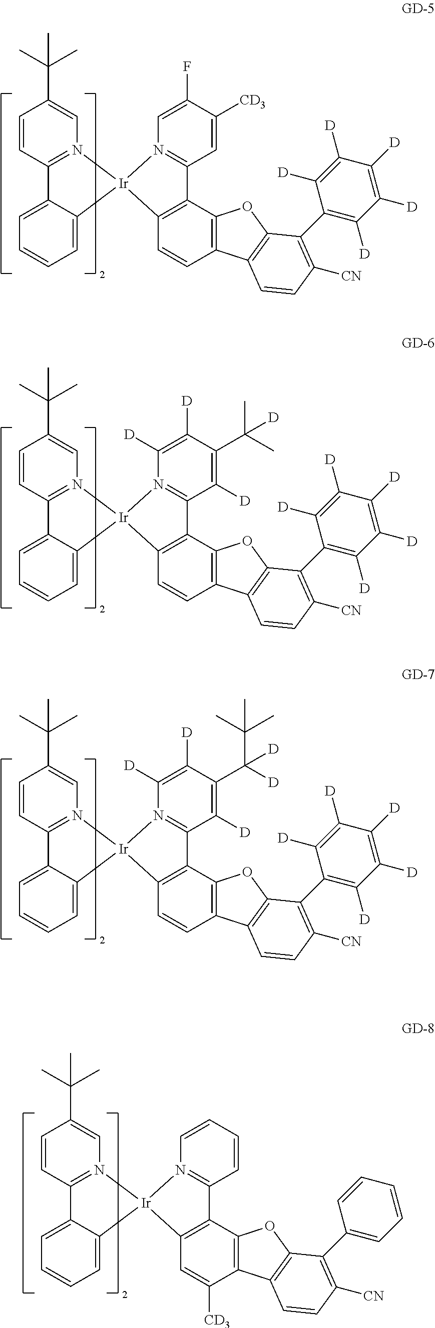

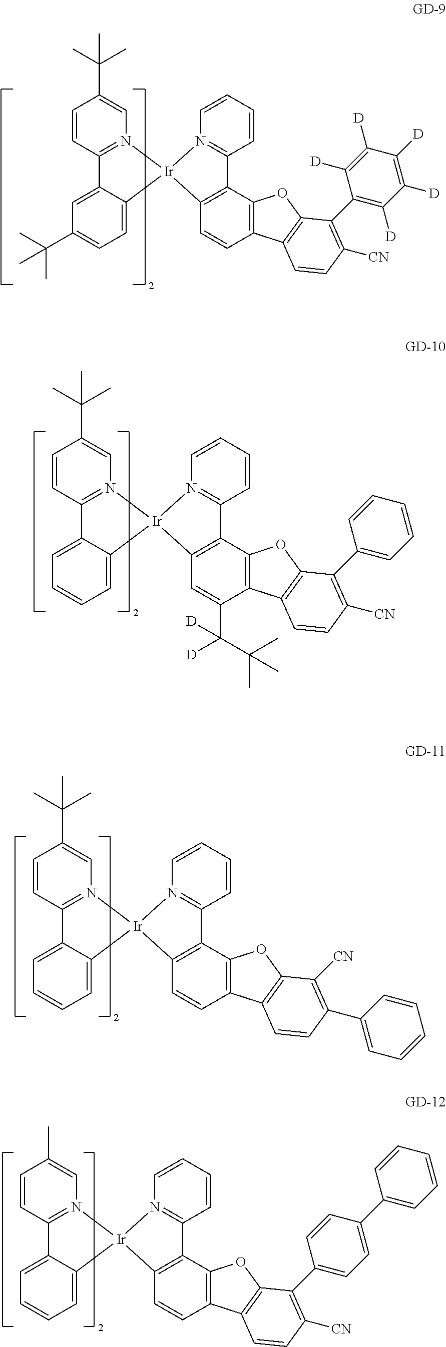

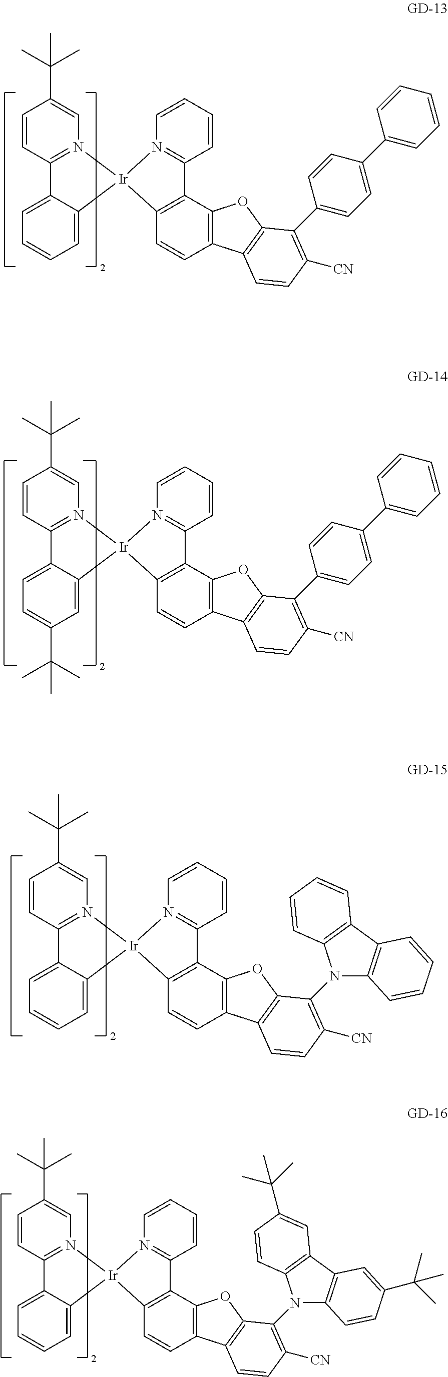

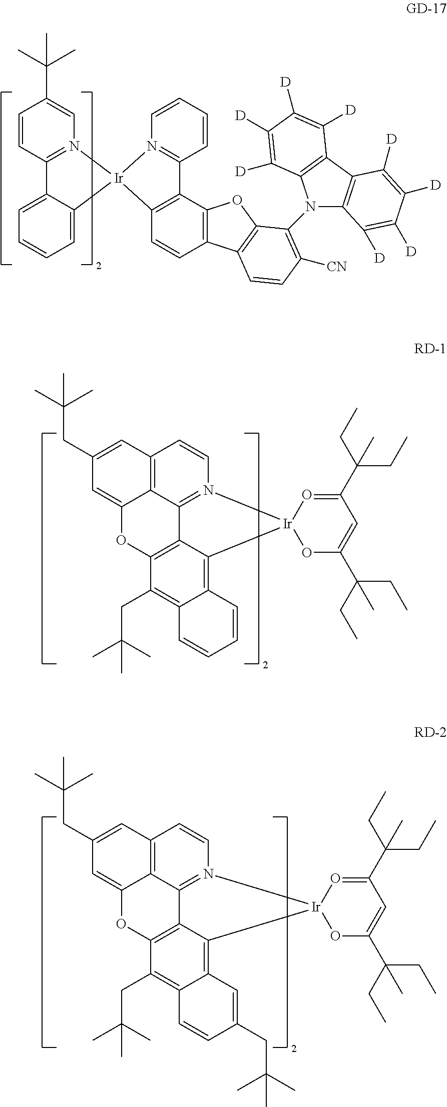

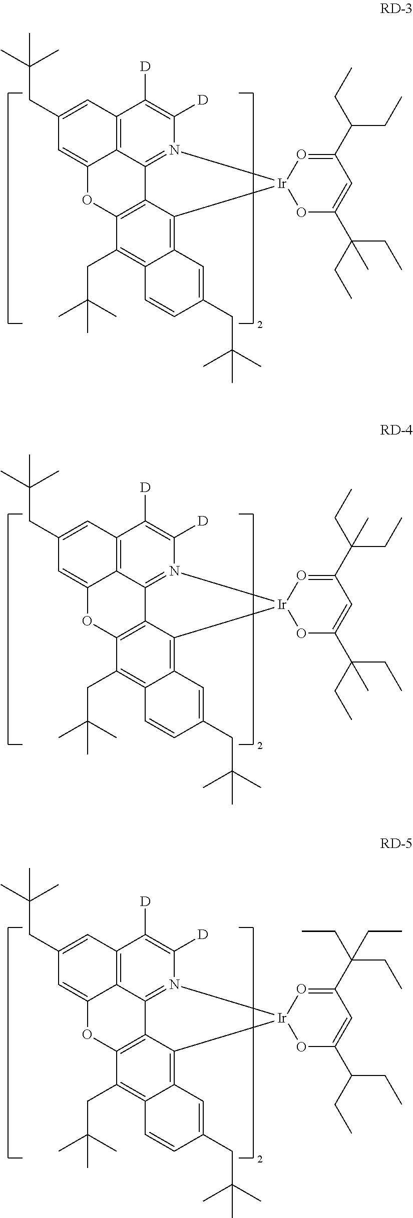

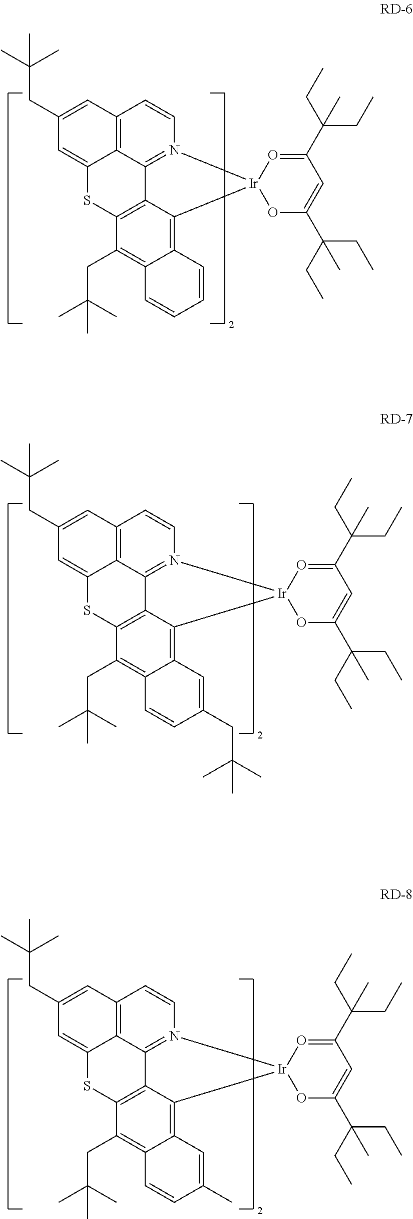

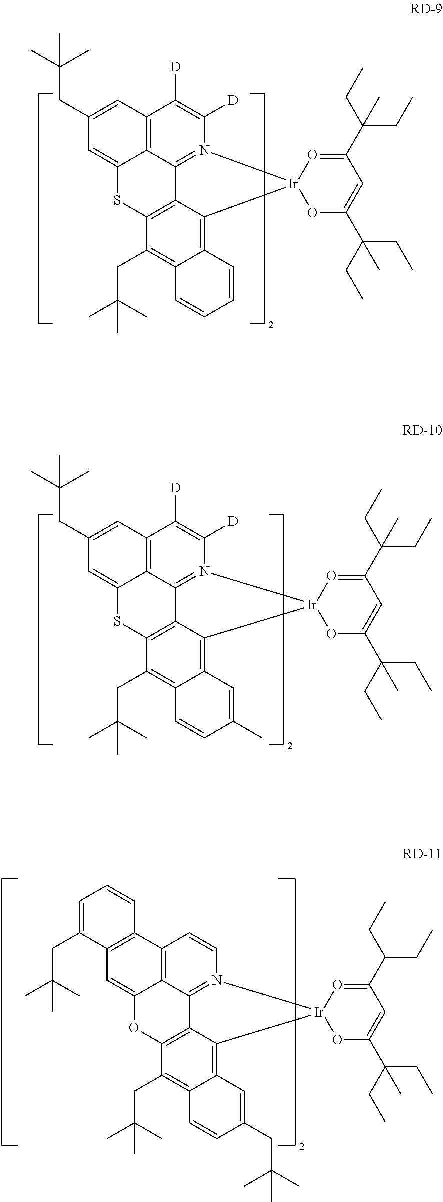

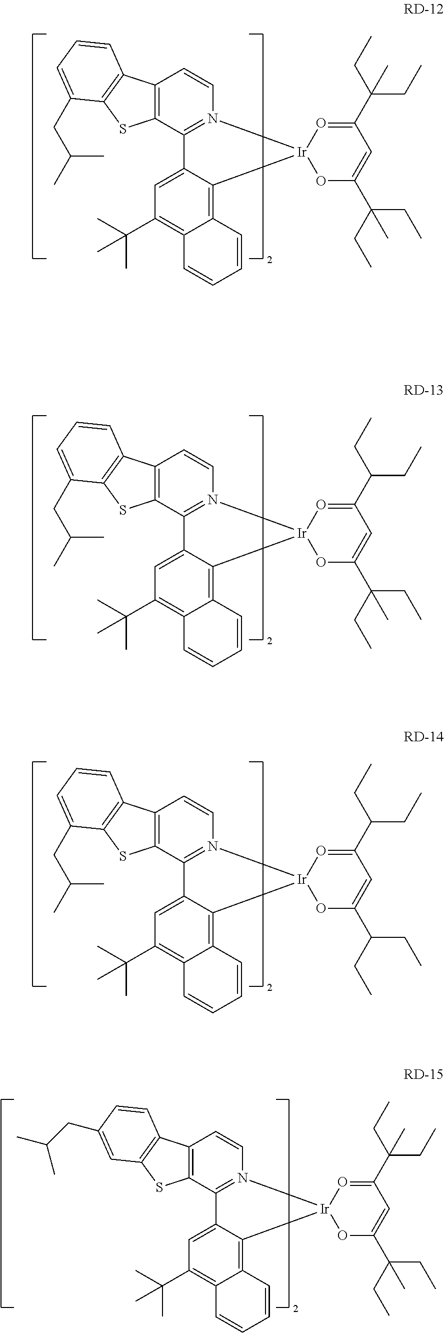

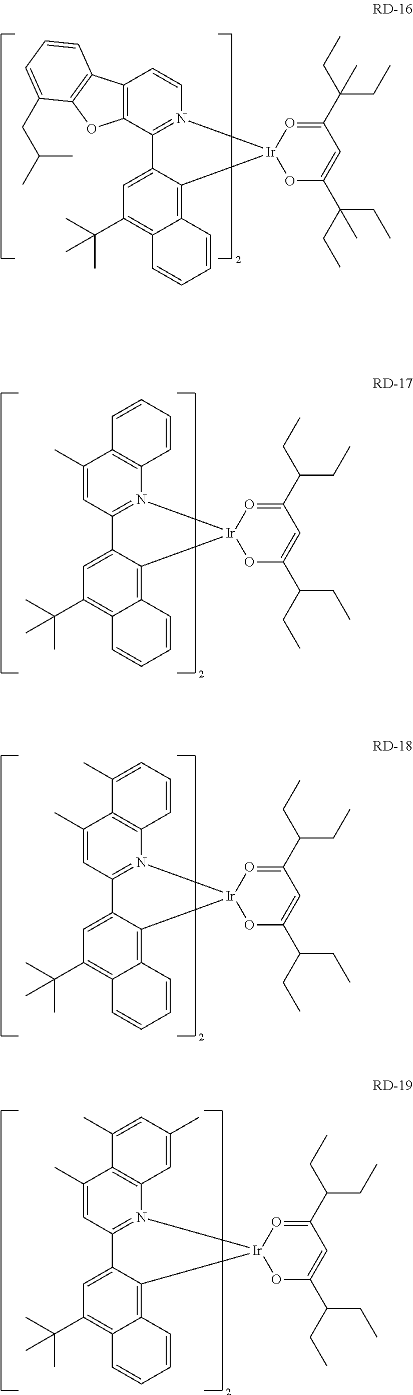

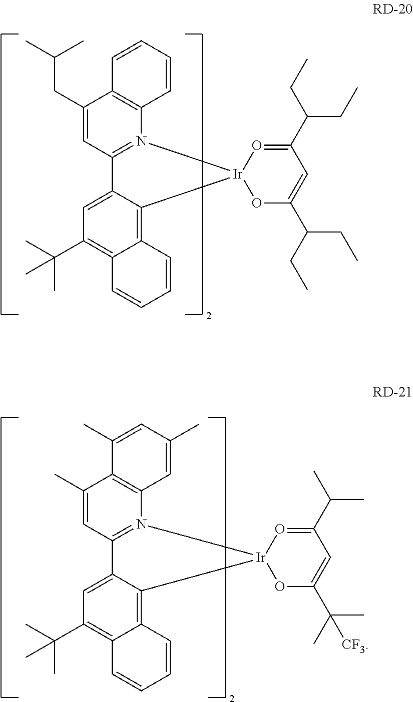

In the present disclosure, a bottom-emission device having the “same” device structure as a top-emission device, or the reference that a bottom-emission device and a top-emission device are “same” in device structure, or other expressions with the same meaning, mean that the bottom-emission device and the top-emission device have the same material layers between the anode and the multi-stack cathode, that is, have the same number of layers, thickness, the same materials and doping proportions, except for a thickness of a material layer for adjusting a microcavity in the top-emission device, which is different due to a microcavity effect. The material layer for adjusting the microcavity is generally a hole transporting layer (HTL) and/or an electron blocking layer (EBL). For example, if the structure of the top-emission device is: first anode/first hole transporting region/first emissive layer/first electron transporting region/first multi-stack cathode, then the device structure of the bottom-emission device having the “same” device structure as the top-emission device is: second anode/second hole transporting region/first emissive layer/first electron transporting region/second multi-stack cathode, wherein material types and doping proportions of each layer of the first hole transporting region and the second hole transporting region are exactly the same, except for the thickness of the material layer for adjusting the microcavity; the top-emission device and the bottom-emission device have exactly the same first emissive layer, and the top-emission device and the bottom-emission device have exactly the same first electron transporting region, both of which may comprise the same one or more organic layers with the same material type, and when the organic layer is formed of two or more materials, the two or more materials also have the same doping (mass) proportion.

The device structure of the top-emission device is the same as the device structure of the bottom-emission device. However, requirements for the electrodes are different due to different light emission directions of the bottom-emission device and the top-emission device. Top-emitted light is emitted from the cathode of the device so that the cathode is required to have a relatively high transmittance, while bottom-emitted light is emitted from the anode of the device so that the anode is required to have a relatively high transmittance. In the bottom-emission device, the anode is generally a transparent or translucent material, including but not limited to ITO, IZO and MoOx (molybdenum oxide), and the material generally has a transparency of greater than 50%; preferably, the transparency is greater than 70%; the cathode is generally a material having a high reflectivity, including but not limited to Al and Ag, and the reflectivity is greater than 70%; preferably, the reflectivity is greater than 90%. In the top-emission device, the anode is generally a material or a combination of materials having a high reflectivity, including but not limited to Ag, Ti, Cr, Pt, Ni, TiN and a combination of the above materials with ITO and/or MoOx (molybdenum oxide), and the reflectivity is generally greater than 50%; preferably, the reflectivity is greater than 80%; more preferably, the reflectivity is greater than 90%; the cathode is generally a translucent or transparent conductive material, including but not limited to a MgAg alloy, MoOx, Yb, Ca, ITO, IZO or a combination thereof, and the conductive material generally has a transparency of greater than 30%; preferably, the transparency is greater than 50%.

The term “exactly the same” in the organic layers or the regions means that the organic materials used in the organic layers or the regions are of the same type. If the organic layer is composed of two or more materials, not only the two or more materials are the same, but also the doping proportions are substantially the same (an error of the doping proportion is within +/−5%, that is, the doping proportion is fluctuated ranging from 95% to 105% of a set doping proportion), and the thicknesses of the organic layers or the regions are also substantially the same (an error of the thicknesses of the organic layers or the regions is within +/−5%, that is, the thickness is fluctuated ranging from 95% to 105% of a set thickness). Here, “the organic materials are of the same type” means that the organic materials have the same chemical structural formula.

Herein, values of highest occupied molecular orbital (HOMO) energy levels and lowest unoccupied molecular orbital (LUMO) energy levels of all the compounds are measured through a cyclic voltammetry (CV) method. The test is conducted using an electrochemical workstation modelled CorrTest CS120 produced by Wuhan Corrtest Instruments Corp., Ltd and using a three-electrode working system where a platinum disk electrode serves as a working electrode, a Ag/AgNO₃ electrode serves as a reference electrode, and a platinum wire electrode serves as an auxiliary electrode. The test is conducted at 25° C., anhydrous DMF is used as a solvent, 0.1 mol/L of tetrabutylammonium hexafluorophosphate is used as a supporting electrolyte, a compound to be tested is prepared into a solution of 10⁻³ mol/L, and nitrogen is introduced into the solution for 10 min for oxygen removal before the test. The parameters of the instrument are set as follows: a scan rate of 100 mV/s, a potential interval of 0.5 mV, and a test window of 1 V to −0.5 V. Herein, all the “HOMO energy levels” and “LUMO energy levels” are represented by negative values. The smaller the value (that is, the larger the absolute value), the deeper the energy level, and the larger the value (that is, the smaller the absolute value), the shallower the energy level.

Herein, “multi-stack cathode” refers to a multi-stack layer composed of a cathode and an organic layer in contact with the cathode. In the top-emission device, “multi-stack cathode” or “first multi-stack cathode” refers to a multi-stack layer composed of a cathode, an EIL and a capping layer (CPL). In the bottom-emission device, “multi-stack cathode” or “second multi-stack cathode” refers to a multi-stack layer composed of a cathode and an EIL. For example, structures of the multi-stack cathodes in the top-emission device and the bottom-emission device are schematically shown in the examples of the present application without limitation, respectively. Among which, the multi-stack cathode in the top-emission is prepared as “metal ytterbium (Yb) with a thickness of 10 Å is firstly evaporated as the electron injection layer (EIL), on which both metal magnesium (Mg) and metal silver (Ag) are simultaneously evaporated as the cathode (10:90, 140 Å), and then on which Compound CPL is evaporated as the capping layer (CPL, 650 Å), whereby the multi-stack structure is formed”. Transmittances of the two-layer structure of Yb 10 Å/Mg:Ag (10:90, 140 Å) in the multi-stack cathode are shown in Table 1, and optical refractive indexes (n values) of the CPL material layer with a thickness of 700 Å at specific wavelength bands are shown in Table 2. The multi-stack cathode in the bottom-emission device is prepared as “Compound Liq with a thickness of 10 Å is firstly evaporated as the electron injection layer (EIL), and then on which metal aluminum (Al) is evaporated as the cathode (1200 Å), whereby the multi-stack structure is formed”. Those skilled in the art may adjust the composition of the multi-stack cathode as needed. For example, a translucent material or combination is selected as the cathode of the top-emission device, such as a MgAg alloy, MoOx, Yb, Ca, ITO, IZO or combinations thereof; a material or a combination having a relatively high reflectivity is selected as the cathode of the bottom-emission device, such as Ag, Ti, Cr, Pt, Ni, TiN and a combination of the above materials with ITO and/or MoOx; a material or a combination of materials having a refractive index of greater than 1.8 in a region of visible light is generally selected as the CPL material. Suitable materials may be selected as the EIL layers in the above “first multi-stack cathode” and “second multi-stack cathode” as needed.

TABLE 1
Transmittances of Yb 10 Å/Mg:Ag 14 Å:126
Å thin film at specific wavelengths

| Wavelength (nm) | Transmittance (%) |
|---|---|
| 460 | 58 ± 3 |
| 530 | 53 ± 3 |
| 620 | 43 ± 3 |

TABLE 2
Optical refractive indexes (n values) of CPL 700
Å thin film at specific wavelengths

| | Refractive |
|---|---|
| Wavelength (nm) | Index n Value |
| 460 | 2.12 ± 0.05 |
| 530 | 1.99 ± 0.05 |
| 620 | 1.88 ± 0.05 |

A method for testing the transmittance of the above-mentioned Yb 10 Å/Mg:Ag (10:90, 140 Å) thin film is as follows: on a quartz plate, metal ytterbium (Yb) with a thickness of 10 Å is firstly evaporated, on which both metal magnesium (Mg) and metal silver (Ag) are simultaneously evaporated as the cathode (10:90, 140 Å), whereby the two-layer structure Yb/Mg:Ag is formed; the test is conducted using an ultraviolet spectrophotometer (modelled UV7600) of SHANGHAI LENGGUANG TECH. CO., LTD to obtain transmittance values at a full wavelength; after three tests, an average value of the transmittances corresponding to 460 nm, 530 nm and 620 nm is taken.

A method for testing the optical refractive index (n value) of the above-mentioned CPL material is as follows: on a silicon wafer, a sample 700 Å thin film is evaporated in an evaporation chamber; the test is conducted using an ellipsometer (modelled ESNano) of BEIJING ELLITOP TECH. CO., LTD to obtain the refractive index n value; after three tests, an average value of the refractive indexes corresponding to 460 nm, 530 nm and 620 nm is taken.

Herein, a method for testing the maximum emission wavelength λₘₐₓ and the full width at half maximum data of the photoluminescence spectrum of the organic emissive doped material is as follows: an organic emissive doped material sample is prepared into a solution with a concentration of 1×10⁻⁶ mol/L by using HPLC-grade of toluene, nitrogen is purged into the prepared solution for five minutes to remove oxygen, the solution is excited with light at a wavelength of 400 nm at room temperature (298 K), a luminescence spectrum of the solution is measured, and spectrum information is directly read from the spectrum, as shown in Table 3. The test instrument is a fluorescence spectrophotometer modelled LENGGUANG F98 produced by SHANGHAI LENGGUANG TECH. CO., LTD.

TABLE 3
Full widths at half maximum (FWHM) and maximum emission
wavelengths (λₘₐₓ) of photoluminescence spectrums
and HOMO energy level data of emissive doped materials

| Emissive | | | |
|---|---|---|---|
| doped | λₘₐₓ | FWHM | HOMO |
| material | (nm) | (nm) | (eV) |
| GD-17 | 528 | 31.82 | −5.213 |
| GD-3 | 528 | 34.43 | −5.199 |
| GDA | 525 | 53.37 | −5.051 |
| RD-5 | 619 | 29.79 | −5.145 |

Herein, “efficiency conversion rate E” refers to a conversion rate between the maximum external quantum efficiency EQE_{A} of the top-emission device and the maximum external quantum efficiency EQE_{B} of the bottom-emission device having the same device structure as the top-emission device at the same current density Jₒ, that is, the efficiency conversion rate E=EQE_{A}/EQE_{B}. In the top-emission device, an emissive doped material adjusts the microcavity by adjusting a thickness of a film of the HTL or the EBL or a combination of the two layers and obtains the maximum external quantum efficiency EQE_{A}; the same emissive doped material is used in the same bottom-emission device as the top-emission device, in this case, second external quantum efficiency measured at the current density Jₒ is EQE_{B}, and 1 mA/cm²<Jₒ≤50 mA/cm²; preferably, 3 mA/cm²<Jₒ≤35 mA/cm²; more preferably, 5 mA/cm²<Jₒ≤15 mA/cm².

Herein, “exciton recombination peak position” refers to a ratio of a position d of a probe layer where the exciton fraction achieves a maximum value to a total thickness of an EML, wherein d represents a distance between an interface (the interface refers to an interface between a layer contacted to the EML on the side of the anode and the EML) and the position of the probe layer. The layer contacted to the EML on the side of the anode includes, but is not limited to, the HTL or the EBL. “Exciton fraction” refers to a ratio of the number of excitons at a certain position in the emissive layer to the total number of excitons in the emissive layer. The exciton fraction reflects how much exciton recombination occurs within a diffusion length of the probe layer and can be used for characterizing a relative relationship of the exciton distribution of the device. The exciton fraction can be calculated according to electroluminescence (EL) spectrum data. Using FIG. 3 as an example, the layer contacted to the EML on the side of the anode is the EBL, then in this case, d represents a distance between the probe layer and an interface of the EBL/EML, and the total thickness of the EML is 400 Å. If the exciton fraction achieves a maximum value at d=0 Å, then the corresponding exciton recombination peak position is in the emissive layer at 0/400=0% of the thickness of the emissive layer from the side close to the anode. If the exciton fraction achieves a maximum value at d=100 Å, then the corresponding exciton recombination peak position is in the emissive layer at 100/400=25% of the thickness of the emissive layer from the side close to the anode. Similarly, when d=200 Å, 300 Å and 400 Å, corresponding exciton recombination peak positions are in the emissive layer at 50%, 75% and 100% of the thickness of the emissive layer from the side close to the anode.

The probe layer mentioned in the above test of exciton recombination peak position generally comprises a probe material, which is generally selected from an emissive doped material which is similar to the emissive doped material in the EML in energy level and electrical performance but red-shifted compared to the maximum emission wavelength of the emissive doped material in the EML. Preferably, an emissive doped material with a maximum emission wavelength red-shifted at least 30 nm is selected as the probe material. Through the comparison of spectral intensities of the device in the case of the presence or absence of a probe at each specific position in the emissive layer, exciton fractions at corresponding positions of the EML are calculated, and the exciton recombination peak position is determined. The top-emission device and the bottom-emission device of the present application are schematically used as an example without limitation. In the present application, in Bottom-emission Devices 1-1 to 1-9, an emissive doped material with a maximum emission wavelength λₘₐₓ of greater than or equal to 500 nm and less than or equal to 600 nm is used, and a probe layer of the device is composed of an emissive layer and a probe material RD01 in the device to be tested, wherein RD01 (a peak wavelength of a photoluminescence spectrum is 620 nm) has a doping proportion of 1%. In Bottom-emission Device 1-10 of the present application, an emissive doped material with a maximum emission wavelength λₘₐₓ of greater than 600 nm and less than or equal to 700 nm is used, and a probe layer of the device is composed of an emissive layer and a probe material (RD02) in the device to be tested, wherein RD02 (a peak wavelength of a photoluminescence spectrum is 649 nm) has a doping proportion of 1%. The exciton fraction can be calculated according to a peak wavelength intensity of the probe material in an electroluminescence (EL) spectrum of the device with the probe layer.

In the case where the top-emission device and the bottom-emission device have the same device structure, the exciton recombination peak position of the bottom-emission device is tested, which may characterize the exciton recombination peak position of the corresponding top-emission device having the same device structure, or the exciton recombination peak position in the top-emission device may move slightly in an anode direction relative to the bottom-emission device tested. The microcavity effect is present in the top-emission device as previously mentioned. Therefore, the exciton recombination peak position in the device is generally tested in the bottom-emission device. When the exciton recombination region peak position in the bottom-emission device is within a certain range, the exciton recombination region peak position in the top-emission device also fluctuates within a small range corresponding to the exciton recombination region peak position in the bottom-emission device. Therefore, studying the exciton recombination region peak position of the bottom-emission device is an efficient and reliable means to study the performance of the top-emission device.

The exciton recombination peak position in the emissive layer of the device can be adjusted in multiple manners, such as a hole/electron injection layer, a hole/electron transporting layer and a hole/electron blocking layer. However, through researches, the inventor of the present application thinks that the EML plays a particularly important role in the exciton recombination position in the OLED device. The EML generally comprises a host material and an emissive doped material, wherein the host material generally comprises a p-type host material, an n-type host material or a bipolar host material according to transporting characteristics of the host material. The host material may be one or more types as needed, for example, two types of host material are comprised in the EML. The difference in transporting characteristic and energy level of the emissive doped material may also affect the transporting of carriers in the EML, thereby affecting the exciton recombination position. Therefore, proportions of multiple types of host material in the EML and a doping concentration of the emissive doped material can be adjusted so that the exciton recombination peak position in the EML is adjusted. For example, when the EML comprises two types of host material, which are the p-type host material and the n-type host material, respectively, a proportion of the p-type host material can be increased to improve a transporting capability of holes in the EML so that the exciton recombination region moves toward a side of the cathode; on the contrary, a proportion of the n-type host material can be increased to provide a transporting capability of electrons in the EML so that the exciton recombination region moves toward a side of the anode. In addition, if an emissive doped material with a very strong hole trapping capability is selected, holes transported to the EML will be quickly trapped by the emissive doped material, and the exciton recombination region will be close to the side of the anode; on the contrary, if the emissive doped material does not have a relatively strong hole trapping capability, the exciton recombination region will be far away from the side of the anode.

Although the top-emission device is a commercial device structure at present, since the top-emission device has an optical microcavity effect, intrinsic characteristics of the material (for example, the luminescence spectrum of the top-emission device cannot reflect intrinsic spectral characteristics of the emissive layer) are covered up, for the top-emission device, thicknesses of some organic layers need to be adjusted (for adjusting the microcavity) to perform a comprehensive evaluation of device performance, and finally, a device structure with the best device performance is obtained. Therefore, the top-emission device is used for evaluating the performance of a new material, thereby increasing the number of experiments and resulting in an increased and relatively high test cost, which is not the most suitable device structure for material screening. The bottom-emission device can well reflect the intrinsic characteristics of the material and is simple to prepare and low in cost so that the structure of the bottom-emission device is mostly used in the initial performance test and screening of the new material. Generally, research and development personnel generally perform preliminary screening on the performance of the new material by using the structure of the bottom-emission device first when developing the new material, and then use a potential material in the top-emission device to perform a performance evaluation to save the time and the cost.

Since organic electroluminescence is current-driven luminescence, quantum efficiency can effectively reflect the performance of the organic electroluminescence and is the most important parameter for measuring the device performance. EQE refers to a ratio of the number of photons finally emitted from the organic electroluminescent device to the number of injected carriers, which reflects the overall luminescence efficiency of the device and is one of the important parameters for evaluating the device performance. Therefore, it is very critical to study the efficiency conversion rate between the top-emission device and the bottom-emission device, which can significantly save the time and cost for material development and screening.

Through researches, the inventor of the present application has found that when the exciton recombination peak position of the bottom-emission device is in the emissive layer within a region greater than 0 and less than or equal to 65% of the thickness of the emissive layer from the side of the anode, the maximum external quantum efficiency conversion rate from the bottom-emission device to the top-emission device having the same device structure is higher, and in this case, the device performance of the top-emission device corresponding to the bottom-emission device can also reach an excellent level. While, for the bottom-emission device with the exciton recombination peak position in a region exceeding 65% of the thickness of the emissive layer from the side of the anode, the maximum external quantum efficiency conversion rate from the bottom-emission device to the top-emission device having the same device structure is lower, and the performance of the top-emission device corresponding to the bottom-emission device is also relatively poor. Moreover, even if EQE of bottom-emission devices is substantially the same in this case, for example, for a device whose EQE is 23% among the bottom-emission devices, if the exciton recombination peak position is controlled so that the maximum external quantum efficiency conversion rate E of the device is greater than 1.625, it can be predicted that the EQE of the top-emission having the same device structure will be greater than 23%*1.625=37%. That is, through researches, it is found in the present disclosure that when the exciton recombination peak position is located in the emissive layer within a region greater than 0% and less than or equal to 65% of the thickness of the emissive layer from the side close to the anode, for the emissive doped material whose maximum emission wavelength λₘₐₓ is greater than or equal to 500 nm and less than or equal to 600 nm, the maximum external quantum efficiency conversion rate from the bottom-emission device to the top-emission device having the same device structure can reach 1.625 or more; for the emissive doped material whose λₘₐₓ is greater than 600 nm and less than or equal to 700 nm, the maximum external quantum efficiency conversion rate from the bottom-emission device to the top-emission device having the same device structure can reach 1.850 or more. This means that a material system of the bottom-emission device can be directly used in the structure of the top-emission device and ideal device performance is obtained, thereby significantly reducing resources and time required for researchers to optimize the top-emission device, accelerating a progress of research and development and reducing a cost of research and development, which is of great significance to the commercial development of an OLED technology.

In the examples of devices, the characteristics of the devices were tested using conventional equipment in the art (including, but not limited to, evaporator produced by ANGSTROM ENGINEERING, optical testing system produced by SUZHOU FATAR, lifetime testing system produced by SUZHOU FATAR, and ellipsometer produced by BEIJING ELLITOP, etc.) by methods well-known to the persons skilled in the art. As the persons skilled in the art are aware of the above-mentioned equipment use, test methods, and other related contents, the inherent data of the sample can be obtained with certainty and without influence, so the above related contents are not further described in the present disclosure.

### EXAMPLE

Hereinafter, the present disclosure is described in more detail with reference to the following examples. The compounds used in the following examples can be readily obtained by those skilled in the art, and therefore the synthesis methods thereof are not described here. Apparently, the following examples are only for the purpose of illustration and are not intended to limit the scope of the present disclosure. Based on the following examples, those skilled in the art can obtain other examples of the present disclosure by conducting improvements on these examples.

### Bottom-Emission Device Example

Bottom-emission Device 1-1: a green phosphorescent bottom-emission organic electroluminescent device 200 was prepared, as shown in FIG. 2.

A glass substrate with a thickness of 0.7 mm was provided. On the glass substrate, indium tin oxide (ITO) with a thickness of 800 Å was pre-patterned for use as a second anode 210. Then, after the substrate was washed with deionized water and a detergent, a surface of ITO was treated with oxygen plasma and UV ozone. The substrate was dried in a glovebox to remove moisture, mounted on a holder and transferred into a vacuum chamber. Organic layers specified below were sequentially evaporated through vacuum thermal evaporation on the anode layer at a rate of 0.01 to 10 Å/s and a vacuum degree of about 10⁻⁶ Torr. Firstly, Compound HI was evaporated as a hole injection layer (HIL, 100 Å) 220, and Compound HT was evaporated as a hole transporting layer (HTL, 350 Å) 230. Then, Compound H1 was evaporated for use as an electron blocking layer (EBL, 50 Å) 240, on which Compound H1, Compound H2 and Compound GD-17 were simultaneously evaporated as a first emissive layer (EML, 48:48:4, 400 Å) 250, Compound H3 was evaporated as a hole blocking layer (HBL, 50 Å) 260, and Compounds ET and Liq were co-deposited as an electron transporting layer (ETL, 40:60, 350 Å) 270. Then, a second multi-stack cathode layer 280 was evaporated. Specifically, Compound Liq with a thickness of 10 Å was evaporated as an electron injection layer (EIL) 280a, and then metal aluminum (Al) was evaporated as a cathode (1200 Å) 280b. The device was transferred back to the glovebox and encapsulated with a glass lid 290 to complete the device.

### Bottom-Emission Device 1-2

The preparation method of Bottom-emission Device 1-2 was the same as that of Bottom-emission Device 1-1, except that in the emissive layer (EML), the ratio of Compound H1, Compound H2 and Compound GD-17 was 47:47:6.

### Bottom-Emission Device 1-3

The preparation method of Bottom-emission Device 1-3 was the same as that of Bottom-emission Device 1-1, except that Compound H1, Compound H2 and Compound GD-3 were simultaneously evaporated as the emissive layer and the ratio of Compound H1, Compound H2 and Compound GD-3 was 48:48:4.

### Bottom-Emission Device 1-4

The preparation method of Bottom-emission Device 1-4 was the same as that of Bottom-emission Device 1-3, except that in the emissive layer (EML), the ratio of Compound H1, Compound H2 and Compound GD-3 was 47:47:6.

### Bottom-Emission Device 1-5

The preparation method of Bottom-emission Device 1-5 was the same as that of Bottom-emission Device 1-1, except that in the emissive layer (EML), the ratio of Compound H1, Compound H2 and Compound GD-17 was 63:31:6.

### Bottom-Emission Device 1-6

The preparation method of Bottom-emission Device 1-6 was the same as that of Bottom-emission Device 1-3, except that in the emissive layer (EML), the ratio of Compound H1, Compound H2 and Compound GD-3 was 63:31:6.

### Bottom-Emission Device 1-7

The preparation method of Bottom-emission Device 1-7 was the same as that of Bottom-emission Device 1-1, except that Compound H1, Compound H2 and Compound GDA were simultaneously evaporated as the emissive layer and the ratio of Compound H1, Compound H2 and Compound GDA was 47:47:6.

### Bottom-Emission Device 1-8

The preparation method of Bottom-emission Device 1-8 was the same as that of Bottom-emission Device 1-7, except that in the emissive layer (EML), the ratio of Compound H1, Compound H2 and Compound GDA was 63:31:6.

### Bottom-Emission Device 1-9

The preparation method of Bottom-emission Device 1-9 was the same as that of Bottom-emission Device 1-7, except that in the emissive layer (EML), the ratio of Compound H1, Compound H2 and Compound GDA was 75:19:6.

Detailed structures and thicknesses of part of the devices of Bottom-emission Devices 1-1 to 1-9 are shown in Table 1. A layer using more than one material is obtained by doping different compounds at their weight ratio as recorded.

TABLE 4
Part of device structures in Bottom-emission Devices 1-1 to 1-9

| | | | | Second |
|---|---|---|---|---|
| | Second | | | Multi-stack |
| No. | Anode | HTL | First Emissive Layer | Cathode |
| Bottom-emission | ITO (800 Å) | HT | H1:H2:GD-17 (48:48:4) | Liq (10 Å)/ |
| Device 1-1 | | (350 Å) | (400 Å) | Al (1200 Å) |
| Bottom-emission | ITO (800 Å) | HT | H1:H2:GD-17 (47:47:6) | Liq (10 Å)/ |
| Device 1-2 | | (350 Å) | (400 Å) | Al (1200 Å) |
| Bottom-emission | ITO (800 Å) | HT | H1:H2:GD-3 (48:48:4) | Liq (10 Å)/ |
| Device 1-3 | | (350 Å) | (400 Å) | Al (1200 Å) |
| Bottom-emission | ITO (800 Å) | HT | H1:H2:GD-3 (47:47:6) | Liq (10 Å)/ |
| Device 1-4 | | (350 Å) | (400 Å) | Al (1200 Å) |
| Bottom-emission | ITO (800 Å) | HT | H1:H2:GD-17 (63:31:6) | Liq (10 Å)/ |
| Device 1-5 | | (350 Å) | (400 Å) | Al (1200 Å) |
| Bottom-emission | ITO (800 Å) | HT | H1:H2:GD-3 (63:31:6) | Liq (10 Å)/ |
| Device 1-6 | | (350 Å) | (400 Å) | Al (1200 Å) |
| Bottom-emission | ITO (800 Å) | HT | H1:H2:GDA (47:47:6) | Liq (10 Å)/ |
| Device 1-7 | | (350 Å) | (400 Å) | Al (1200 Å) |
| Bottom-emission | ITO (800 Å) | HT | H1:H2:GDA (63:31:6) | Liq (10 Å)/ |
| Device 1-8 | | (350 Å) | (400 Å) | Al (1200 Å) |
| Bottom-emission | ITO (800 Å) | HT | H1:H2:GDA (75:19:6) | Liq (10 Å)/ |
| Device 1-9 | | (350 Å) | (400 Å) | Al (1200 Å) |

The structures of the compounds used in the devices are shown as follows:

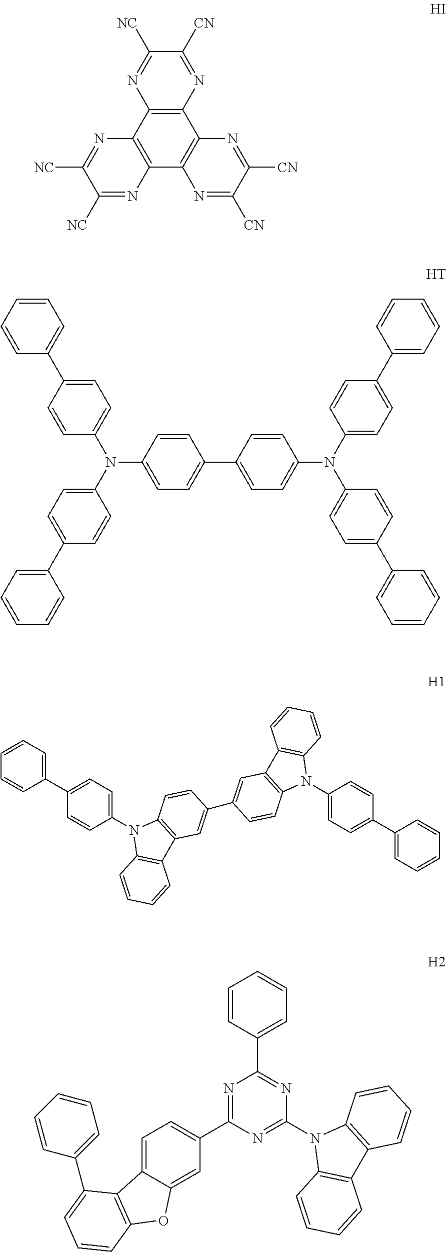 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2nc(-c3ccc4c(c3)oc3cccc(-c5ccccc5)c34)nc(-n3c4ccccc4c4ccccc43)n2)cc1]

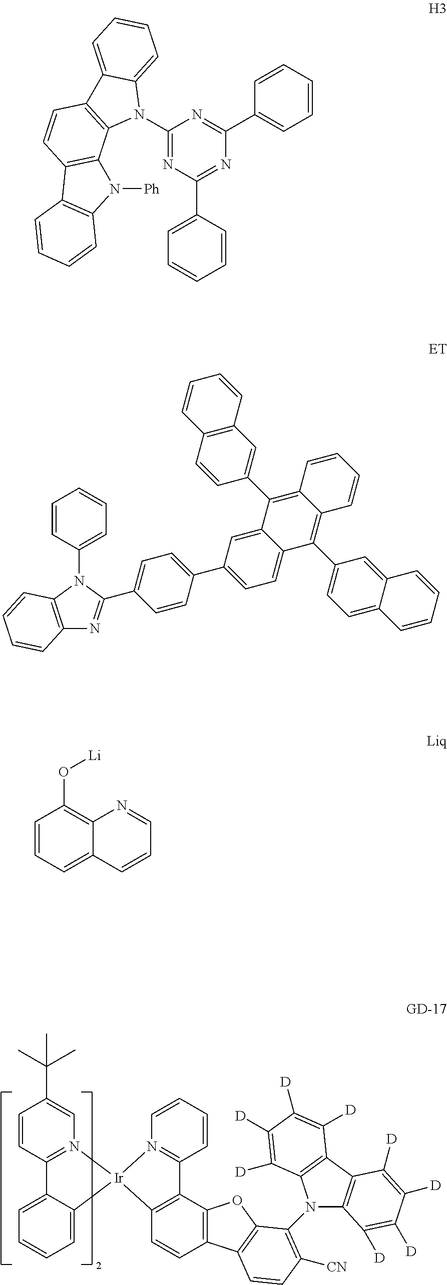

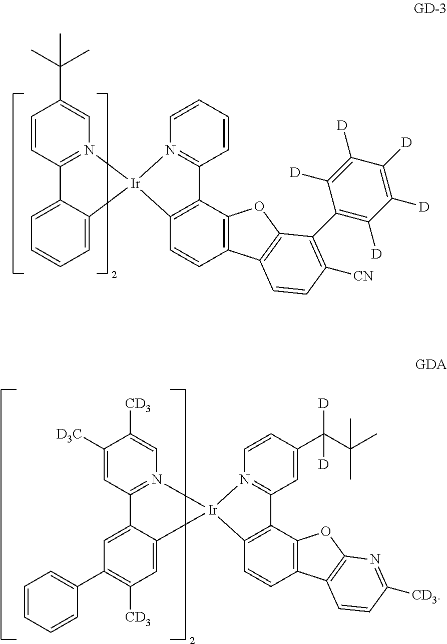

Device performance of Bottom-emission Devices 1-1 to 1-9 is summarized in Table 5. The color coordinate CIE, the maximum emission peak wavelength λₘₐₓ, the full width at half maximum FWHM and the maximum external quantum efficiency EQE_{B} were measured at a current density of 10 mA/cm². The exciton recombination peak position is a position in the emissive layer corresponding to a maximum exciton fraction obtained when the above Bottom-emission Devices 1-1 to 1-9 were tested.

TABLE 5
Device performance of Bottom-emission Devices 1-1 to 1-9

| | | | | | | Exciton Recombination |
|---|---|---|---|---|---|---|
| | | | | | | Peak Position in Region |
| | | | λₘₐₓ | FWHM | EQE_{B} | of Emissive Layer Close |
| No. | CIEx | CIEy | (nm) | (nm) | (%) | to Second Anode |
| Bottom-emission | 0.338 | 0.637 | 531 | 35.6 | 26.22 | 25% |
| Device 1-1 | | | | | | |
| Bottom-emission | 0.346 | 0.632 | 532 | 37.0 | 25.46 | 25% |
| Device 1-2 | | | | | | |
| Bottom-emission | 0.344 | 0.632 | 530 | 37.4 | 24.38 | 25% |
| Device 1-3 | | | | | | |
| Bottom-emission | 0.345 | 0.633 | 532 | 35.9 | 23.02 | 50% |
| Device 1-4 | | | | | | |
| Bottom-emission | 0.343 | 0.634 | 531 | 36.5 | 25.07 | 75% |
| Device 1-5 | | | | | | |
| Bottom-emission | 0.341 | 0.635 | 531 | 35.6 | 23.07 | 75% |
| Device 1-6 | | | | | | |
| Bottom-emission | 0.337 | 0.631 | 525 | 58.2 | 23.52 | 0% |
| Device 1-7 | | | | | | |
| Bottom-emission | 0.335 | 0.633 | 525 | 57.9 | 23.92 | 0% |
| Device 1-8 | | | | | | |
| Bottom-emission | 0.331 | 0.636 | 525 | 55.7 | 23.56 | 75% |
| Device 1-9 | | | | | | |

As can be seen from the above device structures and device performance, through the adjustment of the emissive material in the emissive layer, the exciton recombination peak position can be adjusted. For example, the device structures of Bottom-emission Devices 1-2, 1-4 and 1-7 differ only in different emissive doped materials, while their exciton recombination peaks are differently positioned in the emissive layers. Similarly, through the adjustment of the mass ratio of the host material and the doped material in the emissive layer (including a mass ratio of two host materials), the exciton recombination peak position can also be adjusted. For example, through the comparison of Bottom-emission Devices 1-1, 1-2 and 1-5 and the comparison of Bottom-emission Devices 1-3, 1-4 and 1-6 show that they differ in different mass ratios of host materials and doped materials, while their exciton recombination peaks are differently positioned in the emissive layers.

As can be seen from the above Table 5, the exciton recombination peak positions measured for Bottom-emission Devices 1-1 to 1-4 are located in the emissive layer within a region greater than 0% and less than or equal to 65%, which are respectively at 25%, 25%, 25% and 50%, from the side close to the second anode. The exciton recombination peak positions measured for Bottom-emission Devices 1-5 to 1-9 are in a region outside the region of greater than 0 and less than or equal to 65% from the side of the emissive layer close to the second anode.

Top-emission Device Example: the following are Top-emission Device Examples having the “same” device structure in one-to-one correspondence with the above bottom-emission devices, that is, Top-emission Device 1-1 and the above Bottom-emission Device 1-1 have the “same” device structure, Top-emission Device 1-2 and the above Bottom-emission Device 1-2 have the “same” device structure, and it is true in other cases.

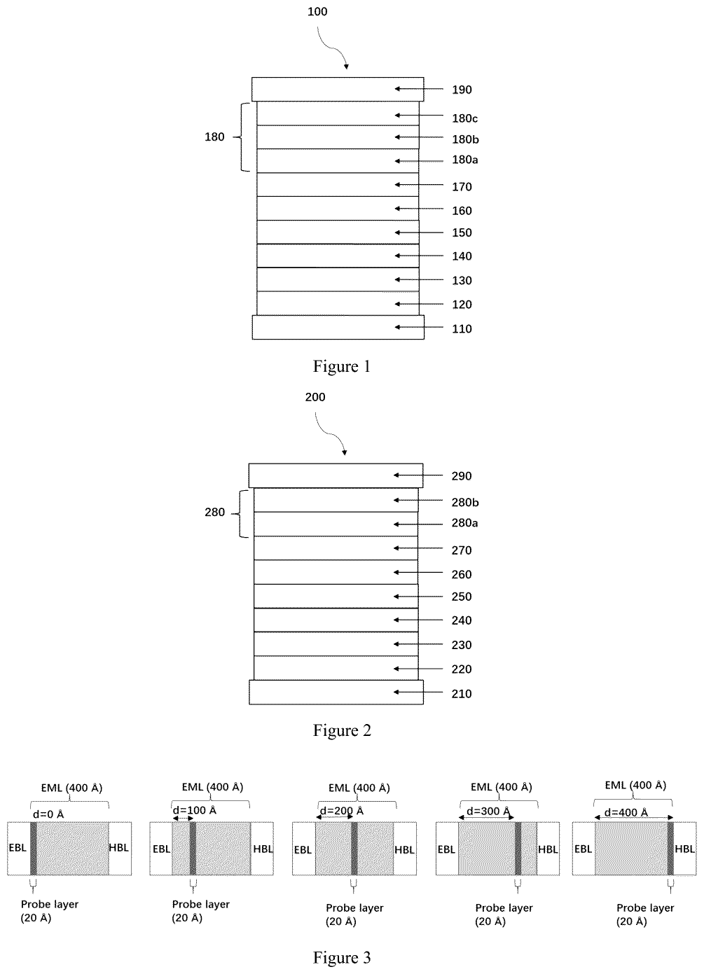

Top-emission Device 1-1: a green phosphorescent top-emission organic electroluminescent device 100 was prepared, as shown in FIG. 1.

Firstly, a glass substrate with a thickness of 0.7 mm was provided. On the glass substrate, indium tin oxide (ITO) 75 Å/Ag 1500Å/ITO 150 Å was pre-patterned for use as a first anode 110. The substrate was dried in a glovebox to remove moisture, mounted on a holder and transferred into a vacuum chamber. Organic layers specified below were sequentially evaporated through vacuum thermal evaporation on the anode layer at a rate of 0.01 to 10 Å/s and a vacuum degree of about 10⁻⁶ Torr. Firstly, Compound HI was evaporated as a hole injection layer (HIL, 100 Å) 120, and Compound HT was evaporated as a hole transporting layer (HTL, ˜1400 Å) 130. The HTL was also used as a microcavity adjustment layer. The thickness of the HTL was adjusted to about 1400 Å to obtain a maximum value of external quantum efficiency EQE. Then, Compound H1 was evaporated for use as an electron blocking layer (EBL, 50 Å) 140, on which Compound H1, Compound H2 and Compound GD-17 were simultaneously evaporated as a first emissive layer (EML, 48:48:4, 400 Å) 150, Compound H3 was evaporated as a hole blocking layer (HBL, 50 Å) 160, and Compounds ET and Liq were co-deposited as an electron transporting layer (ETL, 40:60, 350 Å) 170. Then, a first multi-stack cathode layer 180 was evaporated. Specifically, metal ytterbium (Yb) with a thickness of 10 Å was evaporated as an electron injection layer (EIL) 180a, metal magnesium (Mg) and metal silver (Ag) were simultaneously evaporated as a cathode (10:90, 140 Å) 180b, and then a CPL material was evaporated as a capping layer (CPL, 650 Å) 180c. The device was transferred back to the glovebox and encapsulated with a glass lid 190 to complete the device.

In the following Top-emission Devices 1-2 to 1-9, the HTL was used as the microcavity adjustment layer. The thickness of the HTL was adjusted to about 1400 Å to obtain the maximum value of the external quantum efficiency EQE of the corresponding device.

### Top-Emission Device 1-2

The preparation method of Top-emission Device 1-2 was the same as that of Top-emission Device 1-1, except that in the emissive layer (EML), the ratio of Compound H1, Compound H2 and Compound GD-17 was 47:47:6.

### Top-Emission Device 1-3

The preparation method of Top-emission Device 1-3 was the same as that of Top-emission Device 1-1, except that Compound H1, Compound H2 and Compound GD-3 were simultaneously evaporated as the emissive layer and the ratio of Compound H1, Compound H2 and Compound GD-3 was 48:48:4.

### Top-Emission Device 1-4

The preparation method of Top-emission Device 1-4 was the same as that of Top-emission Device 1-3, except that in the emissive layer (EML), the ratio of Compound H1, Compound H2 and Compound GD-3 was 47:47:6.

### Top-Emission Device 1-5

The preparation method of Top-emission Device 1-5 was the same as that of Top-emission Device 1-1, except that in the emissive layer (EML), the ratio of Compound H1, Compound H2 and Compound GD-17 was 63:31:6.

### Top-Emission Device 1-6

The preparation method of Top-emission Device 1-6 was the same as that of Top-emission Device 1-3, except that in the emissive layer (EML), the ratio of Compound H1, Compound H2 and Compound GD-3 was 63:31:6.

### Top-Emission Device 1-7

The preparation method of Top-emission Device 1-7 was the same as that of Top-emission Device 1-1, except that Compound H1, Compound H2 and Compound GDA were simultaneously evaporated as the emissive layer and the ratio of Compound H1, Compound H2 and Compound GDA was 47:47:6.

### Top-Emission Device 1-8

The preparation method of Top-emission Device 1-8 was the same as that of Top-emission Device 1-7, except that in the emissive layer (EML), the ratio of Compound H1, Compound H2 and Compound GDA was 63:31:6.

### Top-Emission Device 1-9

The preparation method of Top-emission Device 1-9 was the same as that of Top-emission Device 1-7, except that in the emissive layer (EML), the ratio of Compound H1, Compound H2 and Compound GDA was 75:19:6.

Detailed structures and thicknesses of part of layers of the devices of Top-emission Devices 1-1 to 1-9 are shown in Table 6. A layer using more than one material is obtained by doping different compounds at their weight ratio as recorded.

TABLE 6
Part of device structures in Top-emission Devices 1-1 to 1-9

| | | | | First |
|---|---|---|---|---|
| | | | | Multi-stack |
| No. | First Anode | HTL | First Emissive Layer | Cathode |
| Top-emission | ITO (75 Å)/Ag | HT | H1:H2:GD-17 | Yb (10 Å)/Mg:Ag |
| Device 1-1 | (1500 Å)/ITO | (~1400 Å) | (48:48:4) (400 Å) | (1:9) (140 Å)/CPL |
| | (150 Å) | | | (650 Å) |
| Top-emission | ITO (75 Å)/Ag | HT | H1:H2:GD-17 | Yb (10 Å)/Mg:Ag |
| Device 1-2 | (1500 Å)/ITO | (~1400 Å) | (47:47:6) (400 Å) | (1:9) (140 Å)/CPL |
| | (150 Å) | | | (650 Å) |
| Top-emission | ITO (75 Å)/Ag | HT | H1:H2:GD-3 | Yb (10 Å)/Mg:Ag |
| Device 1-3 | (1500 Å)/ITO | (~1400 Å) | (48:48:4) (400 Å) | (1:9) (140 Å)/CPL |
| | (150 Å) | | | (650 Å) |
| Top-emission | ITO (75 Å)/Ag | HT | H1:H2:GD-3 | Yb (10 Å)/Mg:Ag |
| Device 1-4 | (1500 Å)/ITO | (~1400 Å) | (47:47:6) (400 Å) | (1:9) (140 Å)/CPL |
| | (150 Å) | | | (650 Å) |
| Top-emission | ITO (75 Å)/Ag | HT | H1:H2:GD-17 | Yb (10 A)/Mg:Ag |
| Device 1-5 | (1500 Å)/ITO | (~1400 Å) | (63:31:6) (400 Å) | (1:9) (140 Å)/CPL |
| | (150 Å) | | | (650 Å) |
| Top-emission | ITO (75 Å)/Ag | HT | H1:H2:GD-3 | Yb (10 Å)/Mg:Ag |
| Device 1-6 | (1500 Å)/ITO | (~1400 Å) | (63:31:6) (400 Å) | (1:9) (140 Å)/CPL |
| | (150 Å) | | | (650 Å) |
| Top-emission | ITO (75 Å)/Ag | HT | H1:H2:GDA | Yb (10 Å)/Mg:Ag |
| Device 1-7 | (1500 Å)/ITO | (~1400 Å) | (47:47:6) (400 Å) | (1:9) (140 Å)/CPL |
| | (150 Å) | | | (650 Å) |
| Top-emission | ITO (75 Å)/Ag | HT | H1:H2:GDA | Yb (10 Å)/Mg:Ag |
| Device 1-8 | (1500 Å)/ITO | (~1400 Å) | (63:31:6) (400 Å) | (1:9) (140 Å)/CPL |
| | (150 Å) | | | (650 Å) |
| Top-emission | ITO (75 Å)/Ag | HT | H1:H2:GDA | Yb (10 Å)/Mg:Ag |
| Device 1-9 | (1500 Å)/ITO | (~1400 Å) | (75:19:6) (400 Å) | (1:9) (140 Å)/CPL |
| | (150 Å) | | | (650 Å) |

Device performance of Top-emission Devices 1-1 to 1-9 is summarized in Table 7. The color coordinates CIEx and CIEy, the maximum emission peak wavelength λₘₐₓ, the full width at half maximum FWHM and the maximum external quantum efficiency EQE_{A} were measured at a current density of 10 mA/cm². The efficiency conversion rate E is a ratio of the maximum external quantum efficiency EQE of the top-emission device and the corresponding bottom-emission device having the “same” device structure measured at a current density Jₒ=10 mA/cm².

TABLE 7
Device performance and efficiency conversion
rates of Top-emission Devices 1-1 to 1-9

| | | | | | Efficiency |
|---|---|---|---|---|---|
| | | | λₘₐₓ | EQEA | Conversion |
| No. | CIEx | CIEy | (nm) | (%) | Rate E |
| Top-emission | 0.228 | 0.741 | 533 | 43.71 | 1.667 |
| Device 1-1 | | | | | |
| Top-emission | 0.241 | 0.730 | 534 | 42.62 | 1.674 |
| Device 1-2 | | | | | |
| Top-emission | 0.231 | 0.738 | 532 | 42.27 | 1.734 |
| Device 1-3 | | | | | |
| Top-emission | 0.236 | 0.735 | 533 | 38.93 | 1.691 |
| Device 1-4 | | | | | |
| Top-emission | 0.250 | 0.723 | 534 | 39.34 | 1.569 |
| Device 1-5 | | | | | |
| Top-emission | 0.250 | 0.724 | 534 | 34.59 | 1.499 |
| Device 1-6 | | | | | |
| Top-emission | 0.225 | 0.738 | 531 | 38.13 | 1.621 |
| Device 1-7 | | | | | |
| Top-emission | 0.210 | 0.748 | 529 | 38.35 | 1.603 |
| Device 1-8 | | | | | |
| Top-emission | 0.217 | 0.743 | 529 | 36.75 | 1.560 |
| Device 1-9 | | | | | |

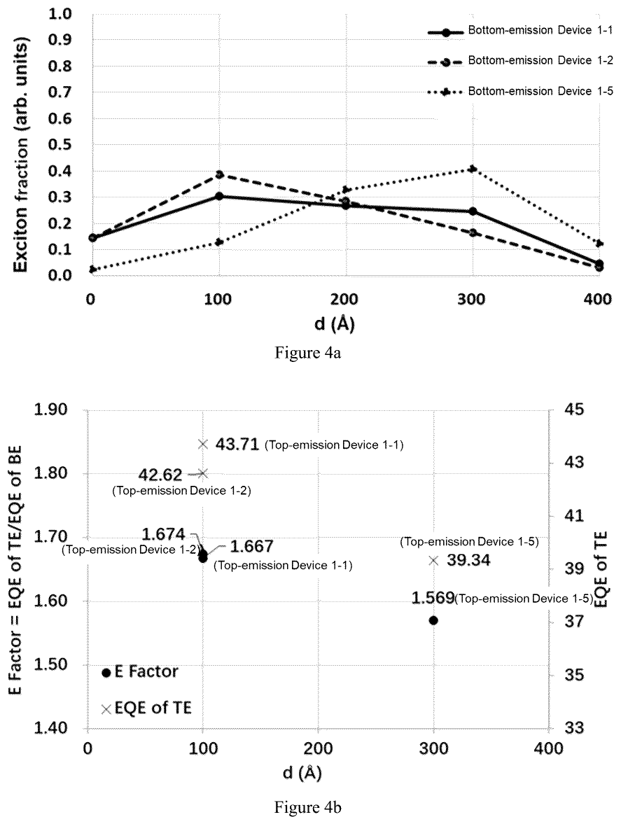

Top-emission Devices 1-1, 1-2 and 1-5 have the same device structures as the above Bottom-emission Devices 1-1, 1-2 and 1-5, respectively. The materials used in Bottom-emission Devices 1-1, 1-2 and 1-5 are all the same, except that the mass ratios of the host materials and the emissive doped material are different in the EMLs, which are H1 :H2:GD-17 (48:48:4), H1 :H2:GD-17 (47:47:6) and H1 :H2:GD-17 (63:31:6) in the EMLs, respectively. FIG. 4a is a schematic diagram illustrating exciton fraction distributions at different positions in EMLs of Bottom-emission Devices 1-1, 1-2 and 1-5. As can be seen from FIG. 4a, through the adjustment of the ratios of P-host, N-host and the emissive doped material GD-17 in the EMLs, the exciton fraction distributions in the bottom-emission devices can be adjusted, wherein each of the maximum values of the exciton fractions of Bottom-emission Devices 1-1 and 1-2, that is, each of the exciton recombination peak positions of Bottom-emission Devices 1-1 and 1-2, is at a position of d=100 Å, and the exciton recombination peak position of Bottom-emission Device 1-5 is at a position of d=300 Å. That is, the exciton recombination peak positions are controlled in the emissive layer at 25%, 25% and 75%, respectively, of the total thickness of the emissive layer from the side close to the anode. In addition, the EQE_{B} of Bottom-emission Devices 1-1, 1-2 and 1-5 are 26.22%, 25.46% and 25.07%, respectively, that is, for Bottom-emission Devices 1-1 and 1-2 whose exciton recombination peak positions are at the position of 25%, the efficiency of Bottom-emission Devices 1-1 and 1-2 is superior to that of Bottom-emission Devices 1-5 where the exciton recombination peak position is at the position of 75%. Further, for the maximum external quantum efficiency conversion rate E from the bottom-emission to the top-emission, the efficiency conversion rates E of Top-emission Devices 1-1 and 1-2 are 1.667 and 1.674, respectively, both higher than 1.569 of Top-emission Device 1-5. If the efficiency conversion rate E of Example 1-1 is 1.569 as that of the comparative example, the EQE of the top-emission device corresponding to Example 1-1 should be 26.22%*1.667=41.14%, and the actual EQE of the top-emission is 43.71%, which is 2.57% significantly higher compared to 41.14% and improved by up to 6.24%; the same is applied to Example 1-2. Therefore, for an emissive doped material whose maximum emission wavelength λₘₐₓ is greater than or equal to 500 nm and less than or equal to 600 nm, when the bottom-emission device satisfies conditions that the exciton recombination peak position is located in the emissive layer within a region greater than 0 and less than or equal to 65% of the thickness of the emissive layer from the side close to the anode and the efficiency conversion rate E is greater than 1.625, not only can relatively excellent bottom-emission device performance be obtained, but better top-emission device performance can also be expected to be obtained.

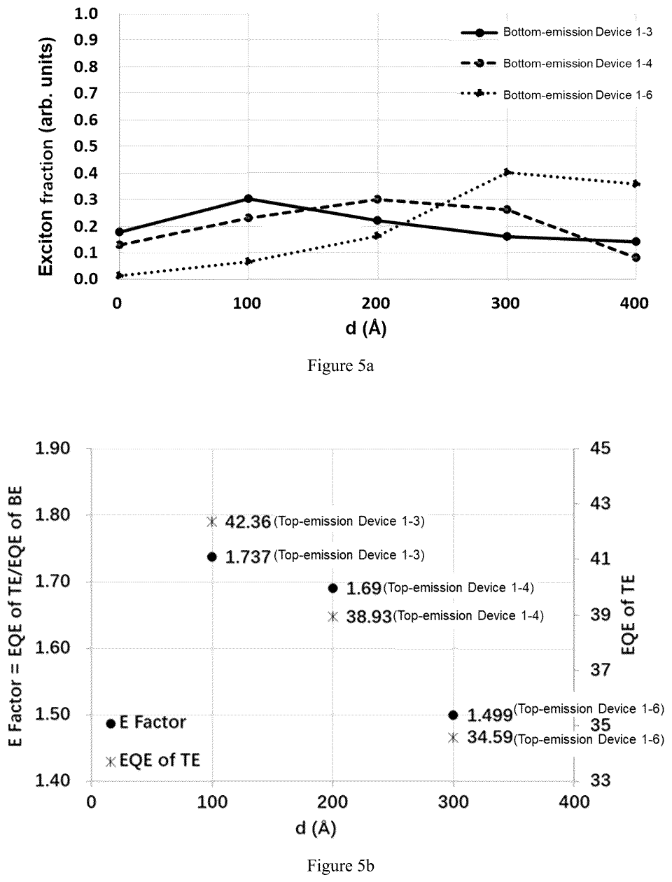

Similarly, Top-emission Devices 1-3, 1-4 and 1-6 have the same device structures as the above Bottom-emission Devices 1-3, 1-4 and 1-6, respectively. The materials used in Bottom-emission Devices 1-3, 1-4 and 1-6 are all the same, except that the mass ratios of the host materials and the emissive doped material are different in the EMLs. FIG. 5a is a schematic diagram illustrating exciton fraction distributions at different positions in EMLs of Bottom-emission Devices 1-3, 1-4 and 1-6, wherein the maximum values of the exciton fractions of Bottom-emission Devices 1-3 and 1-4, that is, the exciton recombination peak positions of Bottom-emission Devices 1-3 and 1-4, are at positions of d=100 Å and 200 Å, respectively, and the maximum value of the exciton fraction of Bottom-emission Device 1-6 is at a position of d=300 Å. That is, the exciton recombination peak positions are controlled in the emissive layer at 25%, 50% and 75%, respectively, of the total thickness of the emissive layer from the side close to the anode. In addition, in the bottom-emission, the EQE of Example 1-3 is 24.38%, which is higher than the EQE (23.07%) of Comparative Example 1-6, that is, for Example 1-3 whose exciton recombination peak position is at the position of 25%, the efficiency of the bottom-emission device is superior to that of Comparative Example 1-6 whose exciton recombination peak position is at the position of 75%. Further, for the maximum external quantum efficiency conversion rate E from the bottom-emission to the top-emission, the efficiency conversion rates E of Top-emission Devices 1-3 and 1-4 are 1.734 and 1.691, respectively, both higher than 1.499 of Top-emission Device 1-6. If the efficiency conversion rate E of Example 1-3 is 1.499 as that of Comparative Example 1-6, the EQE of the top-emission device corresponding to Example 1-3 should be 24.38%*1.499=36.55%. While, the actual EQE of the top-emission is 42.36%, which is 5.81% significantly higher compared to 36.55% and improved by up to 15.9%. The EQE in Example 1-4 is 23.02%, which is substantially equal to the EQE (23.07%) of Comparative Example 1-6. However, for the efficiency conversion rate E from the bottom-emission to the top-emission, the efficiency conversion rate E of Example 1-4 is 1.691, which is higher than 1.499 of Comparative Example 1-2. If the efficiency conversion rate E of Example 1-4 is 1.499 as that of Comparative Example 1-6, the EQE of the top-emission device corresponding to Example 1-4 should be 23.03%*1.499=34.52%. While, the actual EQE of the top-emission is 38.93%, which is 4.41% significantly higher compared to 34.52%. Therefore, for an emissive doped material whose maximum emission wavelength λₘₐₓ of photoluminescence spectrum is greater than or equal to 500 nm and less than or equal to 600 nm, when the bottom-emission device satisfies conditions that the exciton recombination peak position is located in the emissive layer within a region greater than 0 and less than or equal to 65% of the thickness of the emissive layer from the side close to the anode and the efficiency conversion rate E is greater than 1.625, not only can relatively excellent bottom-emission device performance be obtained, but better top-emission device performance can also be expected to be obtained.

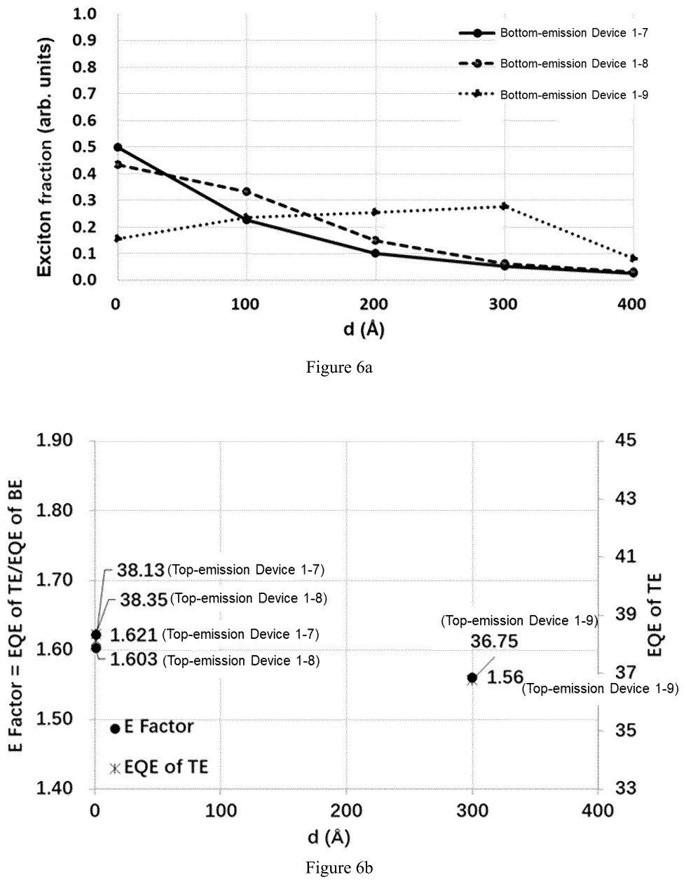

However, Top-emission Devices 1-7, 1-8 and 1-9 have the same device structures as the above Bottom-emission Devices 1-7, 1-8 and 1-9, respectively. In Bottom-emission Devices 1-7, 1-8 and 1-9, although the mass ratios of the host materials and the emissive doped material GDA in the EMLs are also adjusted to be different so that the exciton fraction distributions in the emissive layers of the bottom-emission devices are adjusted, as shown in FIG. 6a, the exciton recombination positions of Bottom-emission Devices 1-7, 1-8 and 1-9 are at 0%, 0% and 75%, respectively. Although the efficiency conversion rates E from the bottom-emission to the top-emission of Top-emission Devices 1-7 and 1-8 are 1.621 and 1.603, respectively, which are a slight improvement compared to the 1.560 of Top-emission Device 1-9. However, since the HOMO energy level of the emissive doped material GDA is relatively shallow, which is only −5.051 eV, a relatively apparent hole trapping phenomenon occurs between the emissive doped material GDA and the host material in the EML so that holes will be trapped on the side of the EML close to the anode once entering the EML, causing the exciton recombination peak position to occur at the interface of the EBL/EML. In this case, there may be leakage of excitons or leakage of un-recombined electrons to the EBL, or even quenching caused by too high a concentration of triplet in a relatively narrow region, thereby resulting in a decrease in device efficiency. Therefore, the exciton recombination peak position should not be at the interface between the EML and the EBL, but should be at a position which is at least 1 nm away from the interface, preferably, 3 nm away from the interface. Moreover, the full width at half maximum of the PL spectrum of the emissive doped material GDA is 53.37 nm, which belongs to a relatively wide spectrum, and even if GDA has performance such as good PLQY, the conversion rate from the bottom-emission to the top-emission is relatively low, and the efficiency of the top-emission device is also relatively low. Therefore, when the HOMO energy level of the emissive doped material is deeper, which is less than −5.100 eV, for example, GD-17 and GD-3 are −5.213 eV and −5.199 eV, respectively; and, when the full width at half maximum of the PL spectrum of the emissive doped material is less than or equal to 50.00 nm, preferably, less than or equal to 45.00 nm, more preferably, less than or equal to 40 nm, for example, GD-17 and GD-3 are 31.82 nm and 34.43 nm, respectively; and in the case where the exciton recombination peak position is greater than 0 and less than or equal to 65% and is not at the interface of EML/EBL, more excellent device performance can be obtained.

Efficiency conversion rates E measured at different current densities Jₒ for Top-emission Devices 1-1 to 1-9 are summarized in Table 8, and efficiency conversion rates E measured at 10 mA/cm², 15 mA/cm², 35 mA/cm² and 50 mA/cm² are recorded.

TABLE 8
Efficiency conversion rates E of Top-emission Devices
1-1 to 1-9 at different current densities

| No. | 10 mA/cm² | 15 mA/cm² | 35 mA/cm² | 50 mA/cm² |
|---|---|---|---|---|
| Top-emission | 1.667 | 1.672 | 1.680 | 1.684 |
| Device 1-1 | | | | |
| Top-emission | 1.674 | 1.680 | 1.700 | 1.706 |
| Device 1-2 | | | | |
| Top-emission | 1.734 | 1.733 | 1.724 | 1.724 |
| Device 1-3 | | | | |
| Top-emission | 1.691 | 1.703 | 1.729 | 1.738 |
| Device 1-4 | | | | |
| Top-emission | 1.569 | 1.573 | 1.589 | 1.589 |
| Device 1-5 | | | | |
| Top-emission | 1.499 | 1.500 | 1.504 | 1.504 |
| Device 1-6 | | | | |
| Top-emission | 1.621 | 1.617 | 1.604 | 1.605 |
| Device 1-7 | | | | |
| Top-emission | 1.603 | 1.597 | 1.581 | 1.571 |
| Device 1-8 | | | | |
| Top-emission | 1.560 | 1.565 | 1.581 | 1.586 |
| Device 1-9 | | | | |

As shown in Table 8, in Top-emission Devices 1-1 to 1-9, when 500 nm≤λₘₐₓ≤600 nm, as long as the corresponding bottom-emission device satisfies that the exciton recombination peak position is located in the emissive layer within a region greater than 0 and less than or equal to 65% of the thickness of the emissive layer from the side close to the anode, it can be satisfied that the efficiency conversion rate E is greater than or equal to 1.625 at different current densities.

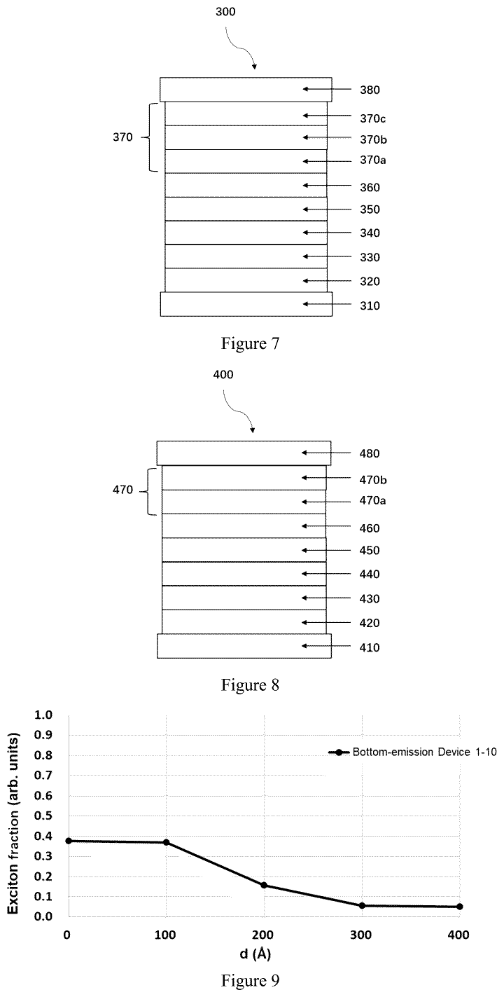

Top-emission Device 1-10: a red phosphorescent top-emission organic electroluminescent device 300 is as shown in FIG. 7.

Firstly, a glass substrate with a thickness of 0.7 mm was provided. On the glass substrate, indium tin oxide (ITO) 75 Å/Ag 1500 Å/ITO 150 Å was pre-patterned for use as a first anode 310. The substrate was dried in a glovebox to remove moisture, mounted on a holder and transferred into a vacuum chamber. Organic layers specified below were sequentially evaporated through vacuum thermal evaporation on the anode layer at a rate of 0.01 to 10 Å/s and a vacuum degree of about 10⁻⁶ Torr. Firstly, Compounds HT1 and PD were simultaneously evaporated as a hole injection layer (HIL, 97:3, 100 Å) 320, and Compound HT1 was evaporated as a hole transporting layer (HTL, ˜2000 Å) 330. The HTL was also used as a microcavity adjustment layer. The thickness of the HTL was adjusted to about 2000 Å to obtain a maximum value of external quantum efficiency EQE. Then, Compound EB was evaporated for use as an electron blocking layer (EBL, 50 Å) 340, on which Compound RH and Compound RD-5 were simultaneously evaporated as a first emissive layer (EML, 97:3, 400 Å) 350, and Compounds ET1 and Liq were co-deposited as an electron transporting layer (ETL, 140:210, 350 Å) 360. Then, a first multi-stack cathode layer 370 of the top-emission was evaporated. Specifically, metal ytterbium (Yb) with a thickness of 10 Å was evaporated as an electron injection layer (EIL) 370a, metal magnesium (Mg) and metal silver (Ag) were simultaneously evaporated as a cathode (14:126, 140 Å) 370b, and then a CPL material was evaporated as a capping layer (CPL, 650 Å) 370c. The device was transferred back to the glovebox and encapsulated with a glass lid 380 to complete the device.

Bottom-emission Device 1-10: a red phosphorescent bottom-emission organic electroluminescent device 400 having the same device structure as Top-emission Device 1-10 was prepared, as shown in FIG. 8.

The preparation method of Bottom-emission Device 1-10 was the same as that of Top-emission Device 1-10, except that a glass substrate with a thickness of 0.7 mm was provided, on the glass substrate, indium tin oxide (ITO) with a thickness of 1200 Å was pre-patterned for use as a second anode 410, then, after the substrate was washed with deionized water and a detergent, a surface of ITO was treated with oxygen plasma and UV ozone, and the substrate was dried in a glovebox to remove moisture, mounted on a holder and transferred into a vacuum chamber; except that Compound HT1 was evaporated as a hole transporting layer (HTL, 400 Å) 430; except that a second multi-stack cathode layer 470 of the bottom-emission was evaporated, specifically, Compound Liq with a thickness of 10 Å was evaporated as an electron injection layer (EIL) 470a, and then metal aluminum (Al) was evaporated as a cathode (1200 Å) 470b.

Part of device structures of Top-emission Device 1-10 and Bottom-emission Device 1-10 are listed in Table 9. A layer using more than one material is obtained by doping different compounds at their weight ratio as recorded.

TABLE 9
Device structures of part of organic layers in Top-
emission Device 1-10 and Bottom-emission Device 1-10

| No. | Anode | HTL | EML | Multi-Cath |
|---|---|---|---|---|
| Top-emission | ITO (75 Å)/ | HT1 | RH:RD-5 | Yb (10 Å)/ |
| Device 1-10 | Ag (1500 Å)/ | (~2000 Å) | (97:3) (400 Å) | Mg:Ag (1:9) |
| | ITO (150 Å) | | | (140 Å)/ |
| | | | | CPL (650 Å) |
| Bottom-emission | ITO (1200 Å) | HT1 | RH:RD-5 | Liq (10 Å)/ |
| Device 1-10 | | (400 Å) | (97:3) (400 Å) | Al (1200 Å) |

The new compounds used in the devices are shown as follows:

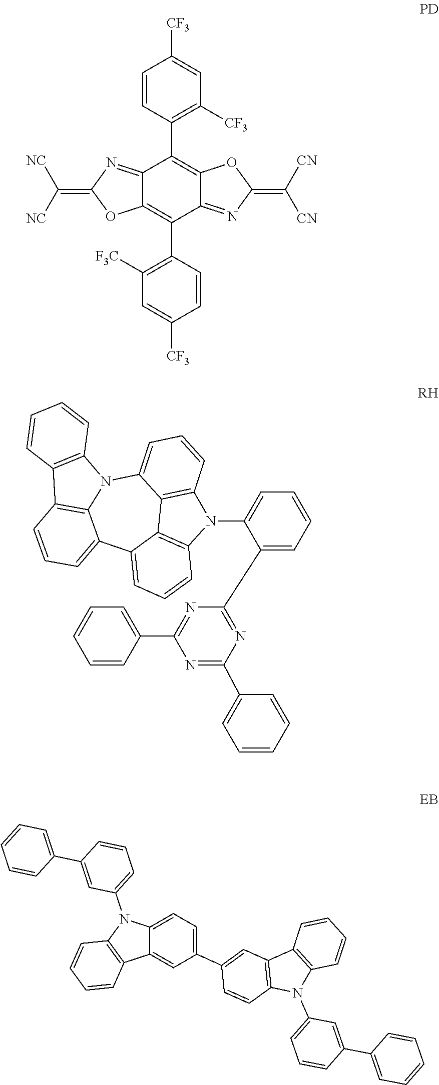 [SMILES: N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2nc(-c3ccccc3)nc(-c3ccccc3-n3c4cccc5c6cccc7c8ccccc8n(c8cccc3c8c54)c67)n2)cc1 ; c1ccc(-c2cccc(-n3c4ccccc4c4cc(-c5ccc6c(c5)c5ccccc5n6-c5cccc(-c6ccccc6)c5)ccc43)c2)cc1]

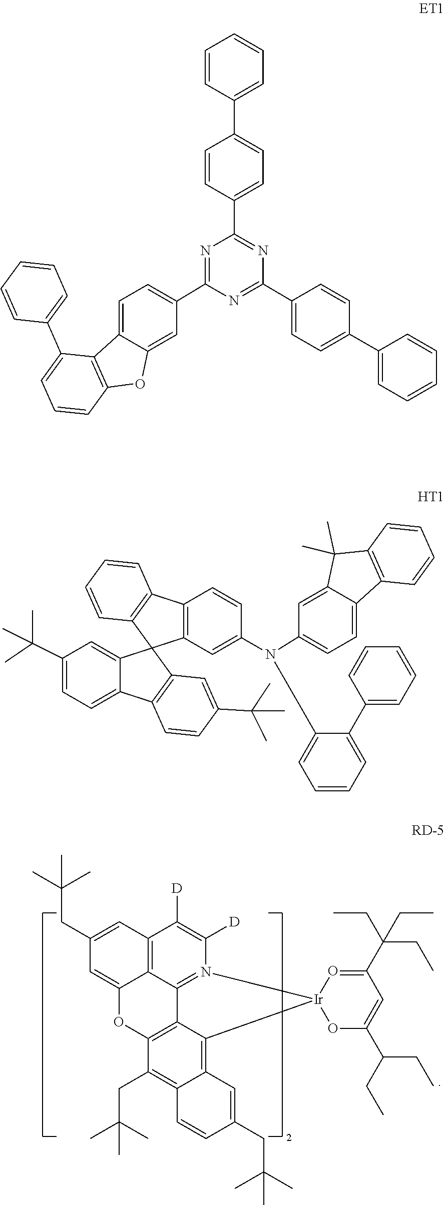

Device performance of Top-emission Device 1-10 and Bottom-emission Device 1-10 is summarized in Table 10 and Table 11. The color coordinates CIEx and CIEy, the maximum emission peak wavelength λₘₐₓ, the full width at half maximum FWHM and the maximum external quantum efficiency EQE were measured at a current density of 10 mA/cm². The maximum external quantum efficiency conversion rate E from the bottom-emission to the top-emission is, as previously described, a ratio of the maximum external efficiency EQE of Top-emission Device 1-10 and Bottom-emission Device 1-10 measured at a current density Jₒ=10 mA/cm². The exciton recombination peak position is a position in the emissive layer corresponding to a maximum exciton fraction obtained when Bottom-emission Device 1-10 was tested.

TABLE 10
Device performance, exciton recombination peak position and
efficiency conversion rate of Bottom-emission Device 1-10

| | | | | | | Exciton |
|---|---|---|---|---|---|---|
| | | | λₘₐₓ | FWHM | EQE | Recombination |
| No. | CIEx | CIEy | (nm) | (nm) | (%) | Peak Position |
| Bottom-emission | 0.681 | 0.318 | 620 | 31.3 | 26.86 | 12.5% |
| Device 1-10 | | | | | | |

TABLE 11
Device performance, exciton recombination peak position and
efficiency conversion rate of Top-emission Device 1-10

| | | | | | Efficiency |
|---|---|---|---|---|---|
| | | | λₘₐₓ | EQE | Conversion |
| No. | CIEx | CIEy | (nm) | (%) | Rate E |
| Top-emission | 0.684 | 0.316 | 619 | 51.30 | 1.910 |
| Device 1-10 | | | | | |

The measured exciton fraction distribution of the above Bottom-emission Device 1-10 is shown in FIG. 9, wherein the exciton fraction of Bottom-emission Device 1-10 is substantially flat in the range of d from greater than 0 to less than 100 Å. Therefore, it can be considered that the exciton fraction of Bottom-emission Device 1-10 reaches a maximum value at d=50 Å. That is, the exciton recombination peak position is in the emissive layer at a position of 12.5% of the total thickness of the emissive layer from the anode side. Moreover, the efficiency conversion rate E from Bottom-emission Device 1-10 to Top-emission Device 1-10 is 1.910. EQE_{B} of the red-light device in Bottom-emission Device 1-10 is of up to 26.86%, which is EQE reached by a very excellent red-light emissive material in the industry. The exciton recombination position is reasonably adjusted so that the top-emission device having the same device structure also reaches EQE_{A} of up to 51.3%. Therefore, for an emissive doped material whose maximum emission wavelength λₘₐₓ of photoluminescence spectrum is greater than 600 nm and less than or equal to 700 nm, when the bottom-emission device satisfies conditions that the exciton recombination peak position is located in the emissive layer within a region greater than 0 and less than or equal to 65% of the thickness of the emissive layer from the side close to the anode and the efficiency conversion rate E is greater than or equal to 1.850, not only can relatively excellent bottom-emission device performance be obtained, but better top-emission device performance can also be expected to be obtained.

To sum up, the present disclosure discloses a high-efficiency top-emission organic electroluminescent device. In the present application, the exciton recombination peak position and the efficiency conversion rate E are adjusted so that a top-emission device having excellent device performance is obtained. Compared to other organic electroluminescent devices, the top-emission organic electroluminescent device has more excellent performance and can exhibit more excellent device performance with the same organic emissive doped material.

It is to be understood that various embodiments described herein are merely examples and not intended to limit the scope of the present disclosure. Therefore, it is apparent to the persons skilled in the art that the present disclosure as claimed may include variations of specific embodiments and preferred embodiments described herein. Many of materials and structures described herein may be substituted with other materials and structures without departing from the spirit of the present disclosure. It is to be understood that various theories as to why the present disclosure works are not intended to be limitative.

What is claimed is:

1. A top-emission organic electroluminescent device, comprising:
an anode, a multi-stack cathode and an emissive layer disposed between the anode and the multi-stack cathode;
wherein the emissive layer comprises an emissive doped material, wherein a maximum emission wavelength of a photoluminescence spectrum of the emissive doped material is λₘₐₓ, and 500 nm≤λₘₐₓ≤700 nm;
the top-emission organic electroluminescent device has a maximum external quantum efficiency conversion rate E, wherein E=EQE_{A}/EQE_{B} and conforms to: when 500 nm≤λₘₐₓ≤600 nm, E≥1.625; when 600 nm<λₘₐₓ≤700 nm, E≥1.850;
EQE_{A} is maximum external quantum efficiency of the top-emission organic electroluminescent device at a current density of Jₒ;
EQE_{B} is maximum external quantum efficiency of a bottom-emission organic electroluminescent device at the current density of Jₒ;
the bottom-emission organic electroluminescent device has a same device structure as the top-emission organic electroluminescent device; and
the emissive layer of the bottom-emission organic electroluminescent device has an exciton recombination region, and an exciton recombination peak position is located in the emissive layer of the bottom-emission organic electroluminescent device within a region greater than 0% and less than or equal to 65% of the thickness of the emissive layer from the side close to the anode.

2. A top-emission organic electroluminescent device, comprising:
an anode,
a cathode and
an emissive layer disposed between the anode and the cathode;
wherein the emissive layer comprises an emissive doped material;
a maximum emission wavelength of a photoluminescence spectrum of the emissive doped material is A max , and 500 nm≤λₘₐₓ≤700 nm; and
the emissive layer has an exciton recombination region, and an exciton recombination peak position is located in the emissive layer within a region greater than 0% and less than or equal to 65% of the thickness of the emissive layer from the side close to the anode.

3. The top-emission organic electroluminescent device according to claim 1, wherein the anode has a reflectivity of greater than or equal to 85% at 550 nm;
preferably, the anode has a reflectivity of greater than or equal to 90% at 550 nm;
more preferably, the anode has a reflectivity of greater than or equal to 95% at 550 nm.

4. The top-emission organic electroluminescent device according to claim 1, wherein the exciton recombination peak position is located in the emissive layer within a region less than 50% of the thickness of the emissive layer from the side close to the anode;
preferably, the exciton recombination peak position is located in the emissive layer within a region less than 40% of the thickness of the emissive layer from the side close to the anode;
more preferably, the exciton recombination peak position is located in the emissive layer within a region less than 30% of the thickness of the emissive layer from the side close to the anode.

5. The top-emission organic electroluminescent device according to claim 1, wherein a distance between the exciton recombination peak position and an interface of the emissive layer on the side close to the anode is greater than 1 nm;
preferably, the distance between the exciton recombination peak position and the interface of the emissive layer on the side close to the anode is greater than 3 nm.

6. The top-emission organic electroluminescent device according to claim 1, wherein when 500 nm≤λₘₐₓ≤600 nm, E≥1.640; preferably, E≥1.660.

7. The top-emission organic electroluminescent device according to claim 1, wherein when 600 nm≤λₘₐₓ≤700 nm, E≥1.900; preferably, E≥2.000.

8. The top-emission organic electroluminescent device according to claim 1, wherein when 500 nm≤λₘₐₓ≤600 nm, a full width at half maximum of the photoluminescence spectrum of the emissive doped material is less than or equal to 53 nm;
preferably, the full width at half maximum of the photoluminescence spectrum of the emissive doped material is less than or equal to 45 nm;
more preferably, the full width at half maximum of the photoluminescence spectrum of the emissive doped material is less than or equal to 40 nm;
most preferably, the full width at half maximum of the photoluminescence spectrum of the emissive doped material is less than or equal to 35 nm.

9. The top-emission organic electroluminescent device according to claim 1, wherein when 600 nm<λₘₐₓ≤700 nm, a full width at half maximum of the photoluminescence spectrum of the emissive doped material is less than or equal to 50 nm;
preferably, the full width at half maximum of the photoluminescence spectrum of the emissive doped material is less than or equal to 40 nm;
more preferably, the full width at half maximum of the photoluminescence spectrum of the emissive doped material is less than or equal to 35 nm;
most preferably, the full width at half maximum of the photoluminescence spectrum of the emissive doped material is less than or equal to 30 nm.

10. The organic electroluminescent device according to claim 1, wherein Jₒ is greater than 5 mA/cm² and less than or equal to 50 mA/cm²;
preferably, Jₒ is greater than 5 mA/cm² and less than or equal to 35 mA/cm²;
more preferably, Jₒ is greater than 5 mA/cm² and less than or equal to 15 mA/cm².

11. The top-emission organic electroluminescent device according to claim 1, wherein when 500 nm≤λₘₐₓ≤600 nm, under a condition that Jₒ is 10 mA/cm², EQE_{B}≥23.0%; when 600 nm≤λₘₐₓ≤700 nm, under the condition that Jₒ is 10 mA/cm 2 , EQE_{B}≥24.0%.

12. The top-emission organic electroluminescent device according to claim 1, wherein when 500 nm≤λₘₐₓ≤600 nm, under a condition that Jₒ is 10 mA/cm², EQE_{A}≥37.0%; when 600 nm<λₘₐₓ≤700 nm, under the condition that Jₒ is 10 mA/cm², EQE_{A}≥45.0%.

13. The top-emission organic electroluminescent device according to claim 1, the emissive layer of the top-emission organic electroluminescent device further comprises a first host material and/or a second host material;
preferably, the emissive layer further comprises a first host material and a second host material, wherein the first host material is a p-type material, and the second host material is an n-type material.

14. The top-emission organic electroluminescent device according to claim 1, wherein when 500 nm≤λₘₐₓ≤600 nm, an HOMO energy level of the emissive doped material <−5.100 eV; when 600 nm<λₘₐₓ≤700 nm, the HOMO energy level of the emissive doped material <−5.110 eV.

15. A display assembly, comprising the top-emission organic electroluminescent device according to claim 1.

16. Use of the top-emission organic electroluminescent device according to claim 1 in an electronic device, an electronic element module, a display device or a lighting device.

17. The top-emission organic electroluminescent device according to claim 2, wherein the exciton recombination peak position is located in the emissive layer within a region less than 50% of the thickness of the emissive layer from the side close to the anode;
preferably, the exciton recombination peak position is located in the emissive layer within a region less than 40% of the thickness of the emissive layer from the side close to the anode;
more preferably, the exciton recombination peak position is located in the emissive layer within a region less than 30% of the thickness of the emissive layer from the side close to the anode.

18. The top-emission organic electroluminescent device according to claim 2, wherein when 500 nm≤λₘₐₓ≤600 nm, a full width at half maximum of the photoluminescence spectrum of the emissive doped material is less than or equal to 53 nm;
preferably, the full width at half maximum of the photoluminescence spectrum of the emissive doped material is less than or equal to 45 nm;
more preferably, the full width at half maximum of the photoluminescence spectrum of the emissive doped material is less than or equal to 40 nm;
most preferably, the full width at half maximum of the photoluminescence spectrum of the emissive doped material is less than or equal to 35 nm.

19. The top-emission organic electroluminescent device according to claim 2, wherein when 600 nm<λₘₐₓ≤700 nm, a full width at half maximum of the photoluminescence spectrum of the emissive doped material is less than or equal to 50 nm;
preferably, the full width at half maximum of the photoluminescence spectrum of the emissive doped material is less than or equal to 40 nm;
more preferably, the full width at half maximum of the photoluminescence spectrum of the emissive doped material is less than or equal to 35 nm;
most preferably, the full width at half maximum of the photoluminescence spectrum of the emissive doped material is less than or equal to 30 nm.

20. The top-emission organic electroluminescent device according to claim 2, wherein a distance between the exciton recombination peak position and an interface of the emissive layer on the side close to the anode is greater than 1 nm;
preferably, the distance between the exciton recombination peak position and the interface of the emissive layer on the side close to the anode is greater than 3 nm.

21. A display assembly, comprising the top-emission organic electroluminescent device according to claim 2.

22. Use of the top-emission organic electroluminescent device according to claim 2 in an electronic device, an electronic element module, a display device or a lighting device.
